(19) United States
(12) Patent Application Publication
(10) Pub. No.: US 2026/0358442 A1
(43) Pub. Date: Nov. 12, 2026

(54) SYSTEMS, METHODS, AND STRUCTURES FOR REDUCING CONDUCTOR CROSSTALK ERROR, IMPROVING COUPLING FACTOR, AND/OR IMPROVING FREQUENCY RESPONSE

(71) Applicant: Allegro MicroSystems, LLC, Manchester, NH (US)

(72) Inventors: Christian Kasparek, Heidelberg (DE); Nathan Shewmon, Braunschweig (DE); Florian Kulla, Annecy (FR); Michael C. Doogue, Bedford, NH (US)

(73) Assignee: Allegro MicroSystems, LLC, Manchester, NH (US)

(21) Appl. No.: 19/201,046

(22) Filed: May 7, 2025

(51) Int. Cl. G01R 33/025; G01R 33/00; G01R 33/07; G01R 33/09

(52) U.S. Cl. CPC G01R 33/025; G01R 33/0005; G01R 33/07; G01R 33/098

(57) ABSTRACT

Disclosed are example systems, methods, and structures for reducing conductor crosstalk error, improving coupling factor, and/or improving frequency response. In particular, disclosed is a system comprising a first conductor structure, a second conductor structure, a shield structure positioned between the conductor structures, and a current sensor device placed in proximity to the first conductor structure for measuring current flowing through the first conductor structure.

### BACKGROUND

Sensors are used to perform various functions in a variety of applications. Some sensors include one or more magnetic field sensing elements, such as a Hall effect element or a magnetoresistive element, to sense a magnetic field associated with proximity or motion of a target object, such as a ferromagnetic object in the form of a gear or a ring magnet, or to sense a current in a conductor, as some examples. Integrated circuits (ICs) incorporating sensors are widely used in automobile control systems and other safety-critical applications.

### SUMMARY

Disclosed are example systems, methods, and structures for reducing conductor crosstalk error, improving coupling factor, and/or improving frequency response. In particular, disclosed is a system comprising a first conductor structure, a second conductor structure, a shield structure positioned between the conductor structures, and a current sensor device placed in proximity to the first conductor structure for measuring current flowing through the first conductor structure. The systems, methods, and structures disclosed herein may allow for multiple conductor structures to be placed in proximity to each other, and may allow a current sensor device to measure an amount of current flowing in one of the conductor structures, while reducing the impact of any current flowing in a neighboring conductor structure on the measurement of the current sensor device. The systems, methods, and structures disclosed herein may also improve a coupling factor between the current flowing through the conductor structure and the current sensor device, thereby improving the accuracy of the current measurements by the current sensor device. The systems, methods, and structures disclosed herein may further reduce impacts of variations in frequency of the current flowing through the conductor structure on the accuracy of the current measurements by the current sensor device.

In accordance with some embodiments, there is provided a system. The system comprises a first conductor structure, and a second conductor structure spaced apart from the first conductor structure along a first dimension. The system also comprises a shield structure positioned between the first conductor structure and the second conductor structure. The system further comprises a sensor device positioned in proximity to the first conductor structure. The sensor device comprises first and second magnetic field sensing elements configured to be sensitive to a magnetic field along the first dimension when current flows through the first conductor structure.

In some embodiments, the shield structure comprises a soft ferromagnetic material.

In further embodiments, the shield structure is shaped like a flat plate.

In still further embodiments, the shield structure is U-shaped.

In some embodiments, the first conductor structure further has a width along the first dimension and a length longer than the width along a second dimension. The first conductor structure further comprises a first portion of the first conductor structure defining a hole passing through the first conductor structure. The first conductor structure also comprises a second portion of the conductor structure defining a first notch out of a first side of the first conductor structure. The first conductor structure still further comprises a third portion of the first conductor structure defining a second notch out of a second side of the first conductor structure. The sensor device is positioned in the hole.

In further embodiments, the system further comprises a third conductor structure spaced apart from the first conductor structure and the second conductor structure along the first dimension.

In still further embodiments, the shield structure comprises a first shield structure. The system further comprises a second shield structure positioned between the second conductor structure and the third conductor structure.

In some embodiments, the shield structure is U-shaped. The shield structure further comprises a first edge positioned between the first conductor structure and the second conductor structure. The shield structure also comprises a second edge positioned between the second conductor structure and the third conductor structure. The shield structure still further comprises a connector portion connecting the first edge and the second edge.

In further embodiments, the first conductor structure, the second conductor structure, and the third conductor structure each comprise a first portion that forms a hole, a second portion that forms a first notch out of a first side, and a third portion that forms a second notch out of a second side.

In still further embodiments, the sensor device is a first sensor device. The first sensor device is positioned in the hole of the first conductor structure. The system further comprises a second sensor device positioned in the hole of the second conductor structure. The system still further comprises a third sensor device positioned in the hole of the third conductor structure.

In some embodiments, at least one of the first and second magnetic field sensing elements is one of a Hall plate element or a tunneling magnetoresistance (TMR) element.

In further embodiments, the first conductor structure is configured to transmit a first alternating current, the second conductor structure is configured to transmit a second alternating current that is phase-shifted from the first alternating current, and the third conductor structure is configured to transmit a third alternating current that is phase-shifted from the first alternating current and that is phase-shifted form the second alternating current.

In still further embodiments, at least one of the first conductor structure or the second conductor structure comprises a busbar.

In some embodiments, at least one of the first conductor structure or the second conductor structure comprises a circuit trace on a printed circuit board (PCB).

In further embodiments, the shield structure comprises at least one of Silicon Iron (SiFe), Nickel Iron (NiFe), ferrite, or magnetic stainless steel.

In still further embodiments, each of the first edge and the second edge extend at least 10 millimeters from the connector portion.

In some embodiments, the shield structure extends at least 5 millimeters in a second dimension orthogonal to the first dimension.

In further embodiments, the first conductor structure comprises a portion that forms a notch out of a side. The sensor device is placed above or below a portion of the conductor structure that passes by the notch.

Furthermore, in accordance with some embodiments, there is provided a method of configuring a current sensor system. The method comprises coupling a first conductor structure to a power source and a load. The method also comprises coupling a second conductor structure to the power source and the load, the second conductor structure being spaced apart from the first conductor structure along a first dimension. The method further comprises positioning a shield structure between the first conductor structure and the second conductor structure. The method still further comprises positioning a sensor device in proximity to the first conductor structure. The sensor device comprises first and second magnetic field sensing elements configured to be sensitive to a magnetic field along the first dimension when current flow through the first conductor structure.

In some embodiments, the shield structure is a first shield structure. The method further comprises coupling a third conductor structure to the power source and the load, the third conductor structure being spaced apart from the first conductor structure and the second conductor structure along the first dimension. The method still further comprises positioning a second shield structure between the second conductor structure and the third conductor structure.

In further embodiments, the method further comprises positioning a first edge of the shield structure between the first conductor structure and the second conductor structure. The method also comprises coupling a third conductor structure to the power source and the load, the third conductor structure being spaced apart from the first conductor structure and the second conductor structure along the first dimension. The method still further comprises positioning a second edge of the shield structure between the second conductor structure and the third conductor structure.

Before explaining example embodiments consistent with the present disclosure in detail, it is to be understood that the disclosure is not limited in its application to the details of constructions and to the arrangements set forth in the following description or illustrated in the drawings. The disclosure is capable of being practiced and carried out in various ways. Also, it is to be understood that the phraseology and terminology employed herein, as well as in the abstract, are for the purpose of description and should not be regarded as limiting.

It is to be understood that both the foregoing general description and the following detailed description are explanatory only and are not restrictive of the claimed subject matter.

### BRIEF DESCRIPTION OF THE DRAWINGS

The accompanying drawings are incorporated in and constitute part of this specification. The drawings, together with the description, illustrate and serve to explain the principles of various example embodiments of the disclosure.

FIG. 1 is a diagram of an example system in which currents in conductors are measured.

FIG. 2 is a diagram of an example system for measuring current in a conductor.

FIG. 3 is another diagram of an example system for measuring current in a conductor.

FIG. 4 is a diagram of an example current sensor device.

FIG. 5A is a diagram of another example system for measuring a current in a conductor.

FIG. 5B is a diagram of still another example system for measuring current in a conductor.

FIG. 6A is a diagram of another example system for measuring current in a conductor.

FIG. 6B is a diagram of another view of the example system for measuring current in the conductor of FIG. 6A.

FIG. 6C is a diagram of an example current sensor device for measuring current in a conductor.

FIG. 7A is a diagram of a system with an arrangement of two example conductor structures positioned in proximity to one another.

FIG. 7B is a diagram of a system with another arrangement of two example conductor structures positioned in proximity to one another.

FIG. 8A is a diagram of an example system including another example conductor structure and a current sensor device.

FIG. 8B is a diagram of an arrangement of two of the example conductors of FIG. 8A positioned in proximity to one another.

FIG. 9 is a diagram of an example system including two example conductor structures positioned in proximity to each other, with an example shield structure positioned between the two conductor structures and example current sensor devices positioned to measure current in each of the conductor structures.

FIG. 10 is a diagram of the example shield structure of FIG. 9.

FIG. 11A is a graph of simulation results, with a plot representing how crosstalk error varies based on shield structure height in a system using the example conductor structures, current sensor devices, and shield structure of FIG. 9.

FIG. 11B is a graph of simulation results, with plots representing how gain error varies based on shield structure height and frequency of a current signal flowing through a conductor structure, in a system using the example conductor structures, current sensor devices, and shield structure of FIG. 9.

FIG. 11C is a graph of simulation results, with plots representing how phase shift of a measured current signal varies based on shield structure height and frequency of the current signal flowing through a conductor structure, in a system using the example conductor structures, current sensor devices, and shield structure of FIG. 9.

FIG. 12 is a diagram of an example system including the two example conductor structures of FIG. 9 positioned in proximity to each other, with the example shield structure of FIG. 9 positioned between the two conductor structures.

FIG. 13 is a graph of simulation results, with plots representing how crosstalk error varies based on shield structure height and based on shield structure material in the system of FIG. 9.

FIG. 14A is a graph of simulation results, with a plot representing a magnetic field in a plane when current is flowing in one example conductor structure in the system of FIG. 9 and when the shield structure in the system of FIG. 9 comprises a soft ferromagnetic material.

FIG. 14B is a graph of simulation results, with a plot representing the magnetic field in another plane when current is flowing in one example conductor structure in the system of FIG. 9 and when the shield structure in the system of FIG. 9 comprises a soft ferromagnetic material.

FIG. 14C is a graph of simulation results, with a plot representing the magnetic field in a plane when current is flowing in one example conductor structure in the system of FIG. 9 and when the shield structure in the system of FIG. 9 does not comprise a soft ferromagnetic material.

FIG. 14D is a graph of simulation results, with a plot representing the magnetic field in another plane when current is flowing in one example conductor structure in the system of FIG. 9 and when the shield structure in the system of FIG. 9 does not comprise a soft ferromagnetic material.

FIG. 15A is a diagram of the example system of FIG. 12, where a shield structure is positioned halfway between the conductor structures of FIG. 12.

FIG. 15B is a graph of simulation results, with plots representing how crosstalk error varies for a current sensor device measuring current flowing in a conductor structure in an arrangement of conductor structures, based on a center-to-center distance between current sensor devices in the arrangement, based on the type of the conductor structures in the arrangement, and based on whether a shield structure is positioned halfway between the conductor structures.

FIG. 16A is a diagram of the example system of FIG. 12, where a shield structure is positioned closer to one of the conductor structures than to the other conductor structure.

FIG. 16B is a graph of simulation results, with plots representing how crosstalk error varies for a current sensor device measuring current flowing in a conductor structure in an arrangement of conductor structures, based on a center-to-center distance between current sensor devices in the arrangement, based on the type of conductor structures in the arrangement, and based on whether a shield structure is positioned closer to one of the conductor structures than to the other conductor structure.

FIG. 17 is a diagram of an example system including three example conductor structures positioned in proximity to each other, with example shield structures positioned between the conductor structures and example current sensor devices positioned to measure current in each of the conductor structures.

FIG. 18A is a diagram of another example system including two example conductor structures positioned in proximity to each other, with an example shield structure positioned between the two conductor structures.

FIG. 18B is a graph of simulation results, with plots representing how crosstalk error varies for a current sensor device measuring current flowing in a conductor structure in an arrangement of conductor structures, based on a center-to-center distance between current sensor devices in the arrangement and based on whether a shield structure is positioned between the conductor structures.

FIG. 19 is a diagram of an example system including two example conductor structures positioned in proximity to each other, with another example shield structure positioned between the two conductor structures.

FIG. 20 is a diagram of the example shield structure of FIG. 19.

FIG. 21 is a graph of simulation results, with plots representing how crosstalk error varies for a current sensor device measuring current flowing in a conductor structure in the system of FIG. 19, based on a center-to-center distance between the conductor structures in the system and based on a height of a shield structure between the conductor structures in the system.

FIG. 22A is a graph of simulation results, with plots representing how gain error varies for a current sensor device measuring current flowing in a conductor structure in the system of FIG. 19, based on a gap between the conductor structures in the system and a frequency of the current flowing through the conductor structure, when a height of the shield structure of the system is 0.5 millimeters.

FIG. 22B is a graph of simulation results, with plots representing how gain error varies for a current sensor device measuring current flowing in a conductor structure in the system of FIG. 19, based on a gap between the conductor structures in the system and a frequency of the current flowing through the conductor structure, when a height of the shield structure of the system is 5 millimeters.

FIG. 22C is a graph of simulation results, with plots representing how gain error varies for a current sensor device measuring current flowing in a conductor structure in the system of FIG. 19, based on a gap between the conductor structures in the system and a frequency of the current flowing through the conductor structure, when a height of the shield structure of the system is 10 millimeters.

FIG. 22D is a graph of simulation results, with plots representing how gain error varies for a current sensor device measuring current flowing in a conductor structure in the system of FIG. 19, based on a gap between the conductor structures in the system and a frequency of the current flowing through the conductor structure, when a height of the shield structure of the system is 15 millimeters.

FIG. 23A is a graph of simulation results, with plots representing how crosstalk varies for a current sensor device measuring current flowing in a conductor structure in the system of FIG. 19, based on a gap between the conductor structures in the system and a frequency of the current flowing through the conductor structure, when a height of the shield structure of the system is 0.5 millimeters.

FIG. 23B is a graph of simulation results, with plots representing how crosstalk varies for a current sensor device measuring current flowing in a conductor structure in the system of FIG. 19, based on a gap between the conductor structures in the system and a frequency of the current flowing through the conductor structure, when a height of the shield structure of the system is 5 millimeters.

FIG. 23C is a graph of simulation results, with plots representing how crosstalk varies for a current sensor device measuring current flowing in a conductor structure in the system of FIG. 19, based on a gap between the conductor structures in the system and a frequency of the current flowing through the conductor structure, when a height of the shield structure of the system is 10 millimeters.

FIG. 23D is a graph of simulation results, with plots representing how crosstalk varies for a current sensor device measuring current flowing in a conductor structure in the system of FIG. 19, based on a gap between the conductor structures in the system and a frequency of the current flowing through the conductor structure, when a height of the shield structure of the system is 15 millimeters.

FIG. 24A is a graph of simulation results, with plots representing how coupling factor varies for a current sensor device measuring current flowing in a conductor structure in the system of FIG. 19, based on a gap between the conductor structures in the system and a frequency of the current flowing through the conductor structure, when a height of the shield structure of the system is 0.5 millimeters.

FIG. 24B is a graph of simulation results, with plots representing how coupling factor varies for a current sensor device measuring current flowing in a conductor structure in the system of FIG. 19, based on a gap between the conductor structures in the system and a frequency of the current flowing through the conductor structure, when a height of the shield structure of the system is 5 millimeters.

FIG. 24C is a graph of simulation results, with plots representing how coupling factor varies for a current sensor device measuring current flowing in a conductor structure in the system of FIG. 19, based on a gap between the conductor structures in the system and a frequency of the current flowing through the conductor structure, when a height of the shield structure of the system is 10 millimeters.

FIG. 24D is a graph of simulation results, with plots representing how coupling factor varies for a current sensor device measuring current flowing in a conductor structure in the system of FIG. 19, based on a gap between the conductor structures in the system and a frequency of the current flowing through the conductor structure, when a height of the shield structure of the system is 15 millimeters.

FIG. 25 is a diagram of an example system including three example conductor structures positioned in proximity to each other, with an example shield structure positioned between the conductor structures.

FIG. 26 is an example process for configuring a system including example conductor structures, a shield structure positioned between the conductor structures, and an example current sensor device, consistent with embodiments of the present disclosure.

The drawings are not necessarily to scale, or inclusive of all elements of a system, emphasis instead generally being placed upon illustrating the concepts, structures, and techniques sought to be protected herein.

### DETAILED DESCRIPTION

Reference will now be made in detail to the embodiments of the disclosure, certain examples of which are illustrated in the accompanying drawings.

In the following description, numerous specific details are set forth regarding the systems, methods, and structures of the disclosed subject matter, and the environment in which such systems, methods, and structures operate, to provide a thorough understanding of the disclosed subject matter. After reading the descriptions provided herein, it will be apparent to one skilled in the art, however, that the disclosed subject matter may be practiced without such specific details. It will also be apparent to one skilled in the art that certain features, which are well known within the art, are not described in detail to avoid unnecessary complication of the description of the systems, methods, and structures described herein. In addition, it will be understood that the embodiments provided below are examples, and that it is contemplated that there are other systems, methods, and structures that are within the scope of the subject matter disclosed herein.

Electric vehicles (EVs) may include one or more alternating current (AC) motors. EVs may also include a traction inverter or power module, which is a power electronics device/system that converts a direct current (DC) supply of power from one or more vehicle batteries to an AC output and that controls a flow of current for use by the vehicle's one or more electric motors. The AC output may then be used to power the electric motor(s), providing drive for the vehicle. Traction inverters are sometimes referred to as variable frequency drives, motor drives, traction drives, and variable speed drives. Traction inverters typically include semiconductor switches such as power transistors, for example, insulated-gate bipolar transistors (IGBTs), silicon carbide (SiC) metal oxide field effect transistors (MOSFETs), or gallium nitride (GaN) MOSFETs, which are controlled by controllers, typically referred to as gate drivers. In electric and hybrid vehicles, the electric motor may also act as a generator during regenerative braking, converting the vehicle's kinetic energy into AC power. This AC power may then be converted to DC power by the traction inverter, allowing the battery to be charged. The gate drivers and associated power transistors of a traction inverter (power module), when considered together, are commonly referred to as power converters. A power converter may be an inverter type (e.g., changing AC power to DC power, and vice versa) or a converter type (e.g., changing DC power at one voltage and/or current to DC power at another voltage and/or current). Power converters may include six power transistors for rectification for three-phase EV motors.

In order to accurately measure current flowing in the power module, a current sensor device comprising magnetic field sensing elements may be used. The current sensor device may measure current flowing in a conductor structure, such as in a bus bar (e.g., a conductive metallic strip or bar) or in a conductive trace of a printed circuit board (PCB), of the power module.

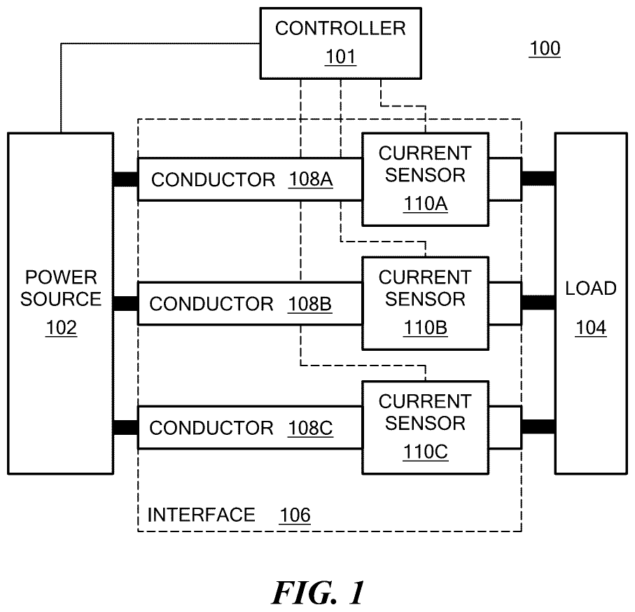

FIG. 1 is a diagram of an example system 100 in which currents in conductor structures are measured. System 100 may, for example, be used in an EV to provide power from a power source 102 (e.g., battery) to a load 104 (e.g., electric motor). An interface 106 may be used to deliver power from power source 102 to load 104.

Interface 106 may include one or more conductor structures. FIG. 1 shows example system 100 as including three conductor structures 108A, 108B, and 108C. Each of conductor structures 108A-108C may include one or more layers of a conductive material (e.g., a metal). In some embodiments, each of conductor structures 108A-108C may also include one or more layers of another conductive material (e.g., another metal). Each of conductors 108A, 108B, 108C may be used to deliver, to load 104, current that is supplied from power source 102. In some systems, one or more of conductor structures 108A, 108B, 108C may be a bus bar. In some systems, all of conductor structures 108A, 108B, 108C may be bus bars. In some systems, one or more of conductor structures 108A, 108B, 108C may be one or more conductive traces on one or more PCBs. In some systems, all of conductor structures 108A, 108B, 108C may be conductive traces on one or more PCBs. In some systems, some of conductor structures 108A, 108B, 108C may be bus bars while others of conductor structures 108A, 108B, 108C may be conductive traces on one or more PCBs.

A controller 101 may be coupled to one or more current sensors. FIG. 1 shows example system 100 as including three current sensor devices 110A, 110B, 110C, each of which may be configured to measure current flowing in a respective conductor structure (e.g., current sensor device 110A measuring current in conductor structure 108A, current sensor device 110B measuring current in conductor 108B, current sensor device 110C measuring current in conductor 108C). The current sensor device(s) may be used to measure the level of current being supplied from power source 102 to load 104 through a respective conductor structure. These measurements may be provided to controller 101, and controller 101 may send signals to adjust operation of power source 102 and/or load 104 in response to the measurements. Controller 101 may be, for example, an electronic control unit (ECU) or other controller of an EV, for example.

As previously discussed, additional circuitry and/or components not shown in FIG. 1 may be used to invert power or convert power provided from power source 102 to load 104.

FIG. 1 shows system 100 as including three conductor structures 108A, 108B, 108C. The three conductor structures may be used to provide three-phase power to load 104. For example, each of conductor structures 108A, 108B, 108C may provide an AC power signal with a phase that is separated by approximately 120 degrees from the other two of the conductor structures. That is, conductor structure 108B may provide an AC power signal that is 120 degrees phase-shifted from the AC power signal of conductor structure 108A, and conductor structure 108C may provide an AC power signal that is 240 degrees phase-shifted from the AC power signal of conductor structure 108A and 120 degrees phase-shifted from the AC power signal of conductor structure 108B.

A person of ordinary skill in the art would recognize that such three-phase power delivery is common in powering electric motors. However, the disclosure is not so limited. Any number of conductor structures providing any combination of currents should be considered to be within the scope of the disclosure herein. For example, any number of conductor structures providing any number of different phases of power may be provided in a system. In some embodiments, six conductor structures providing six different phases of power may be provided in a system. In some systems, multiple conductor structures may provide power with the same phase shift, while other conductor structures may provide power with a different phase shift. In some systems, all of the conductor structures may provide power of the same phase. In some systems, some of the conductor structures may provide DC power, while other conductor structures may provide AC power.

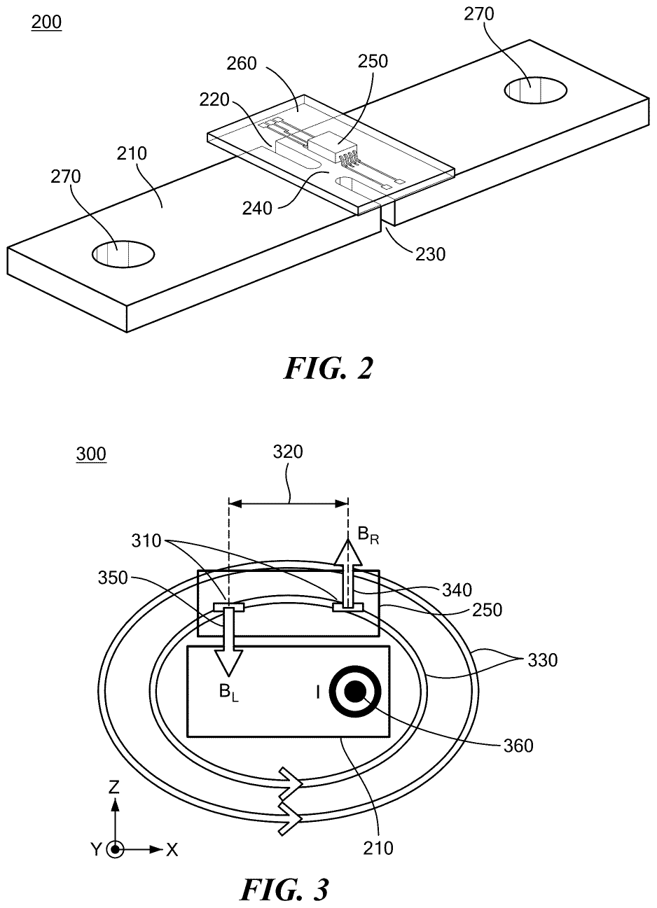

FIG. 2 is a diagram of an example system 200 for measuring current in a conductor structure 210. Conductor structure 210 may be, for example, the conductor structure of one or more of conductor structures 108A, 108B, 108C of FIG. 1. In some systems, conductor structure 210 may also be the conductor structure for each of conductor structures 108A, 108B, 108C of FIG. 1. Conductor structure 210 may be, for example, a bus bar. Conductor structure 210 may be capable of carrying a high current, such as currents ranging anywhere from 100 amperes (A) to greater than 4,000 A, though the disclosure is not so limited. A person of ordinary skill in the art would recognize that characteristics of a conductor structure may be varied to carry any level of current. Conductor structure 210 may be constructed in any of a variety of different shapes, such as flat strips, solid bars, and rods, or as one or more conductive traces on a PCB, as just some examples. Conductor structure 210 may be composed of copper, brass, aluminum, or any other type of conductive material. Conductor structure 210 may alternatively be formed of a combination of different types of conductive materials, such as in layers. In some embodiments, conductor structure 210 may have connection points, shown in FIG. 2 as circular voids, to allow for coupling conductor structure 210 to another component or system, such as a power source (e.g., power source 102), a load (e.g., load 104), or another conductor structure.

In some embodiments, a conductor structure may have one or more notches formed in it. For example, conductor structure 210 shown in FIG. 2 includes two notches, a notch 220 and a notch 230. Notch 220 and notch 230 may each be a void formed, for example, by cutting out (or stamping out) material used to form conductor structure 210. As such, notches 220 and 230 may extend all the way through the entire thickness of conductor structure 210. Forming notches 220 and 230 may cause conductor structure 210 to have a higher current density in a bridge portion 240 of the conductor structure between notches 220 and 230 when current is flowing through conductor structure 210, thereby increasing the magnitude of the magnetic field in proximity to bridge portion 240. A current sensor device may be placed in proximity to bridge portion 240 to measure an amount of current flowing through conductor structure 210. Placing the current sensor device in proximity to bridge portion 240 of conductor structure 210 where current density is higher may result in an improved signal-to-noise ratio (SNR) at the current sensor device, given the increased magnetic field strength near bridge portion 240. As a result, measurements of the current flowing through conductor structure 210 by the current sensor device may be improved by placing the current sensor device in proximity to bridge portion 240.

FIG. 2 shows an example system 200 where a current sensor device 250 is positioned above bridge portion 240 of conductor structure 210. For example, current sensor device 250 may be an integrated circuit (IC) mounted on a printed circuit board (PCB) 260 and positioned in proximity to bridge portion 240. Current sensor device 250 may be mounted on PCB 260 and placed in relation to conductor structure 210, such that current sensor device 250 is positioned directly above (or below) bridge portion 240, with some distance (e.g., air gap) separating current sensor device 250 from conductor structure 210. Current sensor device 250 may alternatively be placed off center (not directly above) bridge portion 240. Current sensor device 250 may be, for example, the Coreless, High Precision, Hall-effect Current Sensor IC (part number ACS37610) sold by Allegro MicroSystems, though the disclosure is not so limited. Current sensor device 250 may be implemented as an IC in a surface-mount thin-shrink small-outline (TSSOP) package, though the disclosure is not so limited. Although FIG. 2 shows current sensor device 250 mounted above bridge portion 240, current sensor device 250 may alternatively be mounted below bridge portion 240. Current sensor device 250 may be mounted such that PCB 260 is between current sensor device 250 and bridge portion 240, as shown in FIG. 2. Alternatively, current sensor device 250 may be mounted such that current sensor device 250 is between bridge portion 240 and PCB 260.

FIG. 3 is a diagram of an example system 300 for measuring current in a conductor. System 300 may be the same as system 200, but shown from a different perspective (i.e., looking at an end of conductor structure 210). As shown in FIG. 3, current (I) 360 may flow through conductor structure 210. In the example shown in FIG. 3, current 360 is flowing toward the viewer (i.e., in a direction parallel to the Y-axis). With current flowing in this direction, a cylindrical magnetic field will be induced around conductor structure 210. The direction of the magnetic field is shown by magnetic field lines 330. For example, using the right-hand rule, it may be determined that the magnetic field curls counterclockwise around conductor structure 210 from the viewer's perspective (i.e., in the plane formed by the X and Z axes) when current flows in a direction toward the viewer (in the Y-axis direction).

System 300 may include a current sensor device 250. Current sensor device 250 may be the same current sensor device as shown in system 200 of FIG. 2. Current sensor device 250 may include one or more magnetic field sensing elements. In the example shown in FIG. 3, current sensor device 250 includes two magnetic field sensing elements 310. The magnetic field sensing elements 310 may be placed apart from each other by a distance 320. Distance 320 may be, for example, between 2 and 3 millimeters (mm) (e.g., 2.58 mm), though the disclosure is not so limited. Magnetic field sensing elements 310 may be Hall effect elements, such as planar Hall elements, though the disclosure is not so limited.

When current flows through conductor structure 210, current sensor device 250 may measure a strength of a magnetic field induced by the current at each of its magnetic field sensing elements (e.g., magnetic field strength B_{R} 340 at one of the magnetic field sensing elements and magnetic field strength B_{L} 350 at the other of the magnetic field sensing elements). In the example of FIG. 3, the planar Hall elements of current sensor device 250 are positioned so as to be maximally sensitive to the magnetic field along the Z-axis, and thus may primarily measure the magnetic field strength along the Z-axis. A difference between the measured magnetic field strengths may then be determined and output as a differential sensed field strength (e.g., B_{diff}), which is proportional to the current flowing through conductor structure 210. For example, the relationship between the current applied to conductor structure 210 and the generated differential field may be described as:

B_{diff}=CF×I Equation 1

where B_{diff} is the generated differential field strength induced between the two magnetic field sensing elements, CF is a differential coupling factor (G (Gauss) /A (Amperes)), and I is the current flowing through conductor structure 210 (in amperes). The differential coupling factor (CF) may correspond to how well the amount of current flowing in the conductor is reflected in the differential magnetic field signal sensed by the current sensor.

Use of two differentially-coupled magnetic field sensing elements in a current sensor device (e.g., current sensor device 250) may allow the current sensor device to be immune to magnetic stray fields. For example, any magnetic field strength attributable to the environment, and not to a current flowing through a conductor structure 210, may be sensed by each of the two magnetic field sensing elements. Because a magnetic field strength attributable to the environment will be approximately equally sensed at the two magnetic field sensing elements (given their close proximity), any magnetic field strength measured by the magnetic field sensing elements that is attributable to the environment will largely cancel out when a difference is taken between the measurements of the two magnetic field sensing elements. That is, common-mode magnetic fields (i.e., common magnetic field strengths sensed by both magnetic field sensing elements) may be cancelled out through use of two differentially-coupled magnetic field sensing elements.

A system, such as system 200 of FIG. 2 and system 300 of FIG. 3, may allow a current sensor device (e.g., current sensor device 250) to measure high currents (e.g., 100 A to greater than 4,000 A) with high accuracy (e.g., accuracy within 1%).

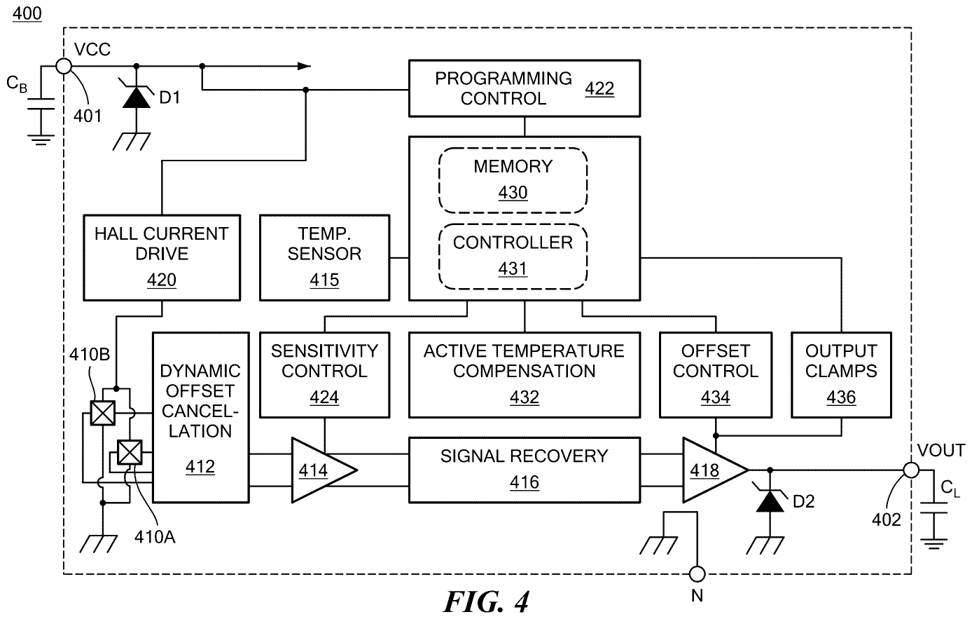

FIG. 4 is a diagram of an example current sensor device 400. In some embodiments, current sensor device 400 may be the same as current sensor device 250.

Current sensor device 400 may be configured to output a signal (e.g., VOUT) at a pin 402. For example, the output signal may be proportional to B_{diff}, where as previously discussed B_{diff}=B_{R} (the magnetic field strength measured by one of the magnetic field sensing elements) B_{L} (the magnetic field strength measured by the other of the magnetic field sensing elements). Although these values are represented as a magnetic field strength (B), one of skill in the art would recognize that the magnetic field sensing elements may in practice output a signal that is proportional to magnetic field strength, such as a voltage that is representative of the magnetic field strength incident on a magnetic field sensing element. For example, each of the magnetic field sensing elements may output a voltage representative of a sensed magnetic field strength, and the differential signal may be the difference between these voltages.

The output signal (e.g., VOUT) may be proportional to the differential signal. For example, a sensor output VOUT may be described as

VOUT=α×B_{diff} Equation 2

where VOUT is an output voltage, B_{diff} is the differential signal (in volts) and α is a constant that corresponds to a sensitivity of the signal path in the current sensor device between B_{diff} and VOUT.

Current sensor device 400 may include a voltage supply pin (e.g., VCC) 401 and an output signal (e.g., VOUT) pin 402. Voltage supply pin 401 may be used for an input power supply or supply voltage for current sensor device 400. A bypass capacitor (e.g., C_{B}) may be coupled between voltage supply pin 401 and a ground reference potential. In some embodiments, voltage supply pin 402 may also be used for programming current sensor device 400. Output signal pin 402 may be used for providing an output signal (e.g., VOUT) to circuits and systems (not shown), such as controller 101 of system 100 of FIG. 1. In some embodiments, output signal pin 402 may be used for programming current sensor device 400. An output load capacitance (e.g., C_{L}) may be coupled between output signal pin 402 and a ground reference potential. The example current sensor device in FIG. 4 includes a first diode D1 coupled between voltage supply pin 401 and a chassis ground, and a second diode D2 coupled between output signal pin 402 and the chassis ground. The example current sensor device in FIG. 4 also includes a pin N coupled to the chassis ground.

Current sensor device 400 may also include drive circuitry for driving one or more magnetic field sensing elements. For example, the current sensor device shown in FIG. 4 includes current drive circuitry 420 for driving Hall effect magnetic field sensing elements 410A and 410B.

Although shown in FIG. 4 as being Hall effect magnetic field sensing elements, the magnetic field sensing elements of a current sensor device (e.g., current sensor device 400) may include any number of different types of magnetic field sensing elements. The term “magnetic field sensing element” may be used herein to describe any of a variety of electronic elements that may be used to sense a magnetic field. A magnetic field sensing element may be any type of element sensitive to a magnetic field. For example, a magnetic field sensing element may be a Hall-effect element (e.g., a Hall plate), a magnetoresistance element, or a magnetotransistor element. For example, a magnetic field sensing element may be a Hall-effect element such as a planar Hall element (e.g., plate), a vertical Hall element (e.g., plate), or a circular vertical Hall (CVH) element (e.g., plate). A magnetic field sensing element may instead be a magnetoresistance element, such as an Indium Antimonide (InSb) element, a giant magnetoresistance (GMR) element (e.g., a spin valve element), an anisotropic magnetoresistance (AMR) element, a tunneling magnetoresistance (TMR) element, or a magnetic tunnel junction (MTJ) element. A magnetic field sensing element may be a receiving coil field sensing element. A magnetic field sensing element may be a single element, or alternatively may include two or more magnetic field sensing elements arranged in one of various configurations, such as a half bridge or a full (Wheatstone) bridge. Depending on the type of sensor device and application requirements, a magnetic field sensing element may be a device made of a type IV semiconductor material such as Silicon (Si) or Germanium (Ge), or of a type III-V semiconductor material such as Gallium-Arsenide (GaAs), or an Indium compound such as Indium-Antimonide (InSb).

Some of the above-described magnetic field sensing elements tend to have an axis of maximum sensitivity that is parallel to a substrate that supports the magnetic field sensing element, while others of the above-described magnetic field sensing elements tend to have an axis of maximum sensitivity that is perpendicular to a substrate that supports the magnetic field sensing element. For example, a planar Hall plate element may have an axis of maximum sensitivity that is perpendicular to a substrate, while a metal-based or metallic magnetoresistance element (e.g., GMR, TMR, AMR) or vertical Hall plate element may have an axis of maximum sensitivity that is parallel to a substrate.

Multiple magnetic field sensing elements in a current sensor device may be of the same type of magnetic field sensing element. For example, current sensor device 400 may include two magnetic field sensing elements 410A and 410B, which may be of the same type. Alternatively, a current sensor device may include different types of magnetic field sensing elements that work together. For example, current sensor device 400 may include two magnetic field sensing elements 410A and 410B, which may be of different types.

Moreover, while current sensor device 400 is shown as including two magnetic field sensing elements, the disclosure is not so limited. A current sensor device (e.g., current sensor device 400) may include any number of one or more magnetic field sensing elements.

Signals (e.g., voltages) output from magnetic field sensing elements 410A and 410B may be coupled to a dynamic offset cancellation circuit 412, which may cancel any voltage offset between the two magnetic field sensing elements (e.g., normalize the voltages output from the two magnetic field sensing elements). Dynamic offset cancellation circuit 412 may take various forms, such as chopping circuitry, and may function in conjunction with an offset control circuit 434 to remove any offset associated with the magnetic field sensing elements and/or amplifier 414. For example, dynamic offset cancellation circuit 412 may include one or more switches configurable to drive the magnetic field sensing elements (e.g., magnetic field sensing elements 410A and 410B) in two or more different directions, such that selected drive and signal contact pairs are interchanged during each phase of a chopping clock signal and such that offset voltages of the different driving arrangements tend to cancel.

Outputs from dynamic offset cancellation circuit 412 may be further coupled to an amplifier 414. Amplifier 414 may amplify the signals received at its inputs, and may output these amplified signals to a signal recovery circuit 416.

A programming control circuit 422 may be coupled between voltage supply pin 401 and a memory 430 and/or controller 431, to provide appropriate programming and control to memory 430 and/or controller 431. Memory 430 may include any suitable type of volatile and/or non-volatile memory. In some embodiments, the memory may be a non-transitory computer-readable medium. By way of example, memory 430 may include a random-access memory (RAM), a dynamic random-access memory (DRAM), an electrically-erasable programmable read-only memory (EEPROM), and/or any other suitable type of memory. Memory 430 may store instructions that, when executed by a controller (e.g., controller 431), cause the controller to carry out certain determinations, steps, processes, and/or calculations.

Controller 431 may include digital and/or analog circuitry. In some embodiments, controller 431 may be a digital controller. Controller 431 may include any suitable type of processing circuitry, such as an application-specific integrated circuit (ASIC), a field programmable gate array (FPGA), a coordinate rotation digital computer (CORDIC) processor, a special-purpose processor, synchronous digital logic, asynchronous digital logic, a general-purpose processor (e.g., microprocessor without interlocked pipelined stages (MIPS) processor, x86 processor), etc. The controller may also include a clock. The clock may, for example, timestamp when voltages (e.g., differential voltages) from magnetic field sensing elements are recorded (e.g., timestamp with an elapsed amount of time measured by the clock), such that determined current measurements and the times at which the current was measured may be stored in memory (e.g., memory 430). One of skill in the art would recognize that the clock need not be internal to the controller, and may instead be an external component connected to the controller.

A sensitivity control circuit 424 may be coupled to amplifier 414 to generate and provide a sensitivity control signal to amplifier 414 to adjust a sensitivity and/or operating voltage of amplifier 414. An active temperature compensation circuit 432 may be coupled to sensitivity control circuit 424, memory 430, controller 431, and/or offset control circuit 434, and may send signals to these components based on a temperature sensed by active temperature compensation circuit 432, such that these components adjust to compensate for a current temperature. For example, active temperature compensation circuit 432 may acquire temperature data from memory 430 and/or controller 431 and may perform necessary calculations or determinations to compensate for changes in temperature (e.g., as detected by temperature sensor 415), if needed.

Offset control circuit 434 may generate and provide an offset signal to a push/pull driver circuit 418 (which may be an amplifier) to adjust a sensitivity and/or operating voltage of driver circuit 418. Output clamps circuit 436 may be coupled between memory 430 and/or controller 431 and driver circuit 418 to limit output voltage when desired (e.g., during fault or error conditions) and/or for diagnostic purposes.

Although not shown, current sensor device 400 may include one or more voltage regulators. A voltage regulator may, for example, convert and/or regulate voltage to provide a stable power supply to the components of current sensor device 400.

Although current sensor device 400 has been described above as outputting a voltage signal (e.g., VOUT) at output pin 402, the disclosure is not so limited. A current sensor device may include any number of different types of output interfaces that are suitable for outputting a signal. An output interface may include one or more of a wired or wireless interface. By way of example, an output interface may include a voltage modulator for sending information along a conductor via voltage pulses, a current modulator for sending information along a conductor via current pulses, an Inter-Integrated Circuit (I²C) interface, a Controller Area Network (CAN) bus interface, a WiFi interface, an Ethernet interface, a Universal Serial Bus (USB) interface, a local area network (LAN) interface, a cellular (e.g., 5G) interface, and/or any other suitable type of interface.

Although FIG. 4 and the discussion above provide certain examples of components and combinations of components that may be used in a current sensor device, the disclosure is not so limited. A current sensor device may use less components than described above, more components than described above, and/or different components than described above.

As discussed above, a system (e.g., system 200 of FIG. 2) that includes a current sensor device (e.g., current sensor device 250) and conductor structure (e.g., conductor structure 210) may allow for accurate current measurements (e.g., within 1% accuracy) to be taken when high currents are flowing through conductor structure 210. However, the accuracy of the current measurements of the current sensor device in such a system may be sensitive to misplacement of the current sensor device (e.g., current sensor device 250) relative to the conductor structure (e.g., conductor structure 210). For example, the air gap between the sensor device and the conductor structure may impact the accuracy of the current sensor device's measurements. Moreover, even if placement of the current sensor device in relation to the conductor structure is carefully calibrated, the relative positioning (e.g., air gap) between the current sensor device and the conductor structure may vary due to vibrations in the system, thermal expansion/contraction depending on temperature, or other factors.

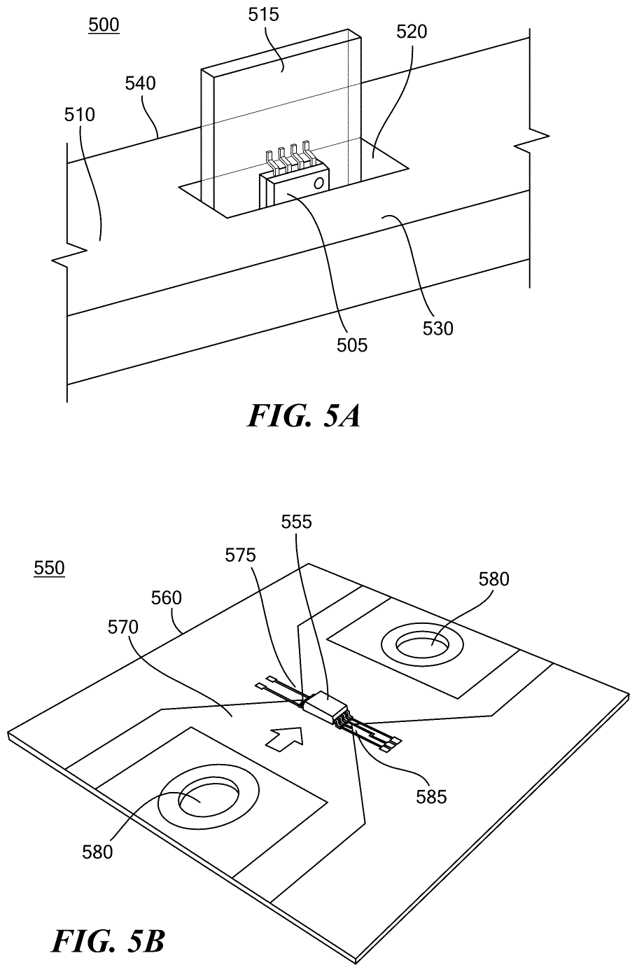

FIG. 5A is a diagram of another example system 500 for measuring a current in a conductor. Example system 500 may include a conductor structure 510, a current sensor 505, and a PCB 515 on which current sensor 505 is mounted.

Conductor structure 510 may be, for example, one or more of conductor structures 108A, 108B, 108C of FIG. 1. Conductor structure 510 may be, for example, a bus bar. Like conductor structure 210, conductor structure 510 may be capable of carrying a high current, such as currents ranging anywhere from 100 A to greater than 4,000 A, though the disclosure is not so limited. Conductor structure 510 may be constructed in any of a variety of different shapes, such as flat strips, solid bars, and rods as just some examples. Conductor structure 510 may be composed of copper, brass, aluminum, or any other type of conductive material. Conductor structure 510 may alternatively be formed of a combination of different types of conductive materials, such as in layers. Conductive structure 510 may have connection points (not shown), such as circular voids, at its ends to allow for coupling conductor structure 510 to another component or system, such as a power source (e.g., power source 102), a load (e.g., load 104), or another conductor structure.

A hole 520 (or slit) is also formed in conductor structure 510. Hole 520 may extend through the thickness of conductor structure 510. Hole 520 may be formed by cutting or stamping out material to form conductive structure 510.

As shown in FIG. 5A, conductor structure 510 includes two conductive bridges 530, 540 adjacent hole 520. Conductive bridges 530, 540 may allow current to pass along conductor structure 510. As discussed above with respect to conductor structure 210, bridges 530, 540, being narrower in width than the overall conductive structure, may have a higher current density than in the rest of conductor structure 510, allowing a current sensor device (e.g., current sensor device 505) placed in proximity to bridges 530, 540 to measure current with greater accuracy.

As shown in FIG. 5A, a current sensor device (e.g., current sensor device 505) may be positioned inside hole 520 of conductor structure 510. Current sensor device 505 may be the same as current sensor device 250 or current sensor device 400, though the disclosure is not so limited. By positioning a current sensor device inside of a hole of the conductor structure, the accuracy of the current sensor device's current measurements may be less sensitive to misplacements of the current sensor device relative to the conductive structure than in system 200 of FIG. 2. Current sensor device 505 may be mounted on a PCB 515. In some embodiments, PCB 515 may be the same as PCB 260, though the disclosure is not so limited.

FIG. 5B is a diagram of still another example system 550 for measuring current in a conductor. Example system 550 may include a conductor structure 570, a current sensor device 555, and a PCB 560 on which conductor structure 570 and current sensor device 555 are mounted.

Conductor structure 570 may be, for example, one or more of conductor structures 108A, 108B, 108C of FIG. 1. Conductor structure 570 may be, for example, one or more conductive traces on a PCB (e.g., PCB 560). Conductor structure 570 may be capable of carrying a high current, such as currents ranging anywhere from 100 A to greater than 4,000 A, though the disclosure is not so limited. The traces of conductor structure 570 may be etched in a variety of different shapes or patterns. The traces of conductor structure 570 may be composed of any type of conductive material, such as copper, brass, aluminum, or some other type of conductive material. The traces of conductor structure 570 may alternatively be formed of a combination of different types of conductive materials, such as in layers. Conductor structure 570 may have connection points, shown in FIG. 5B as circular voids 580, at its ends to allow for coupling conductor structure 570 to another component or system, such as a power source (e.g., power source 102), a load (e.g., load 104), or another conductor structure.

Conductor structure 570 shown in FIG. 5B includes two notches formed in it, notch 575 and notch 585. As discussed above with respect to conductive structure 210, the width of conductor structure 570 is narrower in the portion where notches 575, 585 are present. As a result, this portion of conductor structure 570 may have a higher current density than in the rest of conductor structure 570, allowing current sensor device 555 placed in proximity to this portion (e.g., above or below this position) to measure current with greater accuracy.

As shown in FIG. 5B, current sensor device 555 and conductor structure 570 may be fixed to the same substrate, which in the example of FIG. 5B is PCB 560. By fixing a current sensor device and conductor structure to the same substrate, the accuracy of the current sensor device's current measurements may be less sensitive to misplacements of the current sensor device relative to the conductive structure than in system 200 of FIG. 2.

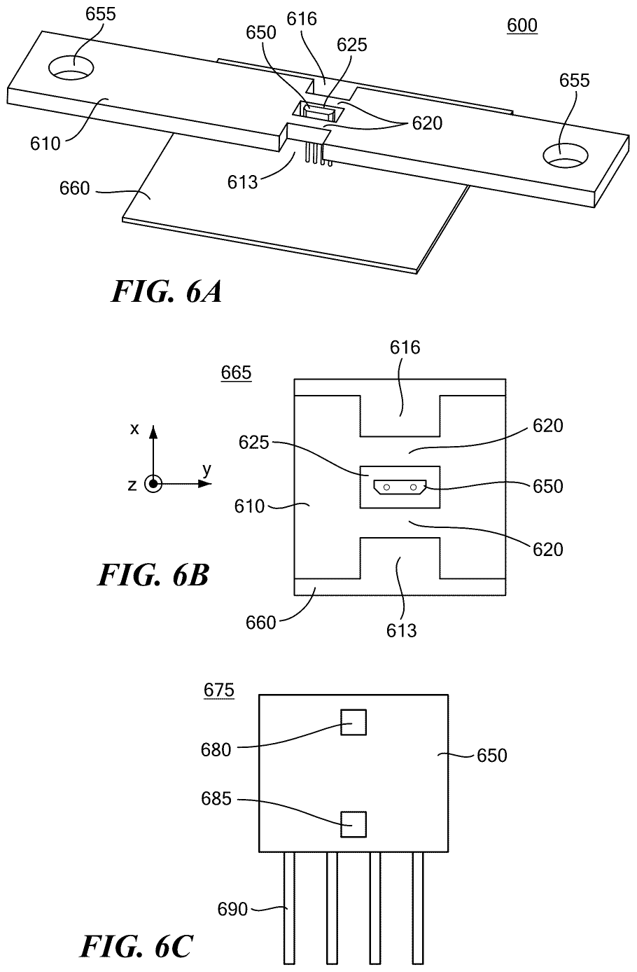

FIG. 6A is a diagram of another example system 600 for measuring current in a conductor structure. Example system 600 may include a conductor structure 610, a current sensor device 650, and a PCB 660 on which current sensor device 650 is mounted.

Conductor structure 610 may be, for example, one or more of conductor structures 108A, 108B, 108C of FIG. 1. Conductor structure 610 may be, for example, a bus bar. Like conductor structure 210, conductor structure 610 may be capable of carrying a high current, such as currents ranging anywhere from 100 A to greater than 4,000 A, though the disclosure is not so limited. Conductor structure 610 may be constructed in a variety of different shapes, such as flat strips, solid bars, and rods as just some examples. Conductor structure 610 may be composed of copper, brass, aluminum, or any other type of conductive material. Conductor structure 610 may alternatively be composed of a combination of different types of conductive materials, such as in layers. Conductor structure 610 may have connection points, shown in FIG. 6A as circular voids, at its ends to allow for coupling conductor structure 610 to another component or system, such as a power source (e.g., power source 102), a load (e.g., load 104), or another conductor structure.

Conductor structure 610 in FIG. 6A includes two notches formed in it, notch 613 and notch 616. The notches of conductor structure 610 may be wider along a length of the conductor, and less deep along a width of the conductor, than the notches of conductor structure 210. Notches 613 and 616 may extend through a thickness of conductor structure 610, as shown in FIG. 6A. A hole 625 (or slit) is also formed in conductor structure 610. Hole 625 may extend through the thickness of conductor structure 610. Hole 625, notches 613, 616, and/or the holes at the ends of conductor structure 610 may be formed by cutting or stamping out material used to form conductive structure 610.

As shown in FIG. 6A, conductor structure 610 includes two conductive bridges 620 adjacent the notches and hole of the conductor structure. Conductive bridges 620 may allow current to pass along conductor structure 610. As discussed above with respect to conductor structure 210, bridges 620, being narrower in width than the overall conductive structure, may have a higher current density than in the rest of conductor structure 610, allowing a current sensor device (e.g., current sensor device 650) placed in proximity to bridges 620 to measure current with greater accuracy. Conductor structure 610 may be referred to as a “dual bridge” or “vertical slit” conductor structure herein.

As shown in FIG. 6A, a current sensor device (e.g., current sensor device 650) may be positioned inside hole 625 of conductor structure 610. By positioning a current sensor device inside a hole of the conductor structure, the accuracy of the current sensor device's current measurements may be less sensitive to misplacements of the current sensor device relative to the conductor structure than in system 200 of FIG. 2.

A current sensor device in a TSSOP package, such as sensor device 250, sensor device 505, or sensor device 555, may be positioned in a hole of a conductor structure (see, e.g., FIG. 5A). However, positioning a current sensor device in a TSSOP package in a hole of a conductor structure may be challenging, given that the TSSOP package may need to be mounted on a PCB. A current sensor device may instead be implemented in a single in-line package (SIP) package, such as sensor device 650 of FIG. 6A. Other than the different packaging, current sensor device 650 may be designed similarly to current sensor device 250, current sensor device 505, and/or current sensor device 555. For example, current sensor device 650 may be implemented as current sensor device 400 of FIG. 4. As shown in FIG. 6A, when implemented in a SIP package, a PCB 660 to which current sensor device 650 is connected may be positioned outside conductor structure 610, such that only current sensor device 650 is positioned in hole 625. Although shown as being positioned below conductor structure 610, PCB 660 may be positioned above conductor structure 610, or anywhere in proximity to conductor structure 610 such that current sensor device 650 may be connected to PCB 660. In some systems, a PCB 660 may not even be required, and current sensor device 650 may be coupled directly to one or more external components (e.g., controller 101) via one or more wires.

FIG. 6B is a diagram 665 of another view of the example system for measuring current in the conductor of FIG. 6A. For example, FIG. 6B shows a portion of system 600 of FIG. 6A, viewed from above. As shown in FIG. 6B, current sensor device 650 is positioned in hole 625 of conductor structure 610, and is connected to a PCB 660. Hole 650 and notches 613, 616 form two bridges 620, over which current may flow through conductor structure 610.

FIG. 6C is a diagram 675 of an example current sensor device 650 for measuring current in a conductor. As shown in FIG. 6C, current sensor device 650 may include a SIP package, in which the various components (see, e.g., current sensor device 400 of FIG. 4) of the current sensor device may be housed. Current sensor device 650 may also include one or more pins 690 for supplying power to current sensor device 650 and/or for providing signals to/from current sensor device 650. As previously discussed, a current sensor device may include one or more magnetic field sensing elements. FIG. 6C shows an example current sensor device 650 including two magnetic field sensing elements 680, 685, which may be planar Hall effect elements. As shown in FIG. 6C, the magnetic field sensing elements may be positioned apart from one another by some distance, such as in a range between 2-3 millimeters (mm) (e.g., 2.58 mm) apart, though the disclosure is not so limited. In some embodiments, the magnetic field sensing elements may be substantially vertically aligned, as shown in FIG. 6C, though the disclosure is not so limited. Current sensor device 650 may be positioned in hole 625 of conductor structure 610, such that magnetic field sensing elements 680, 685 are maximally sensitive to a magnetic field along an X-axis direction (see FIG. 6B). For example, if magnetic field sensing elements 680, 685 are planar Hall effect elements, then when current sensor device 650 is positioned in hole 625, the sensitive plane of the planar Hall effect elements may face towards bridges 620.

As previously discussed with respect to FIG. 1, it may be desirable to place multiple conductor structures in proximity to each other. For example, the conductor structures may be utilized in a system that provides AC currents having different phases (e.g., a three-phase power system, a six-phase power system). In a three-phase power system, for example, three conductor structures may be utilized, where a second conductor structure provides current that is phase-shifted by 120 degrees from a first conductor structure, and where a third conductor structure provides current that is phase-shifted by 240 degrees from the first conductor structure, and by 120 degrees from the second conductor structure.

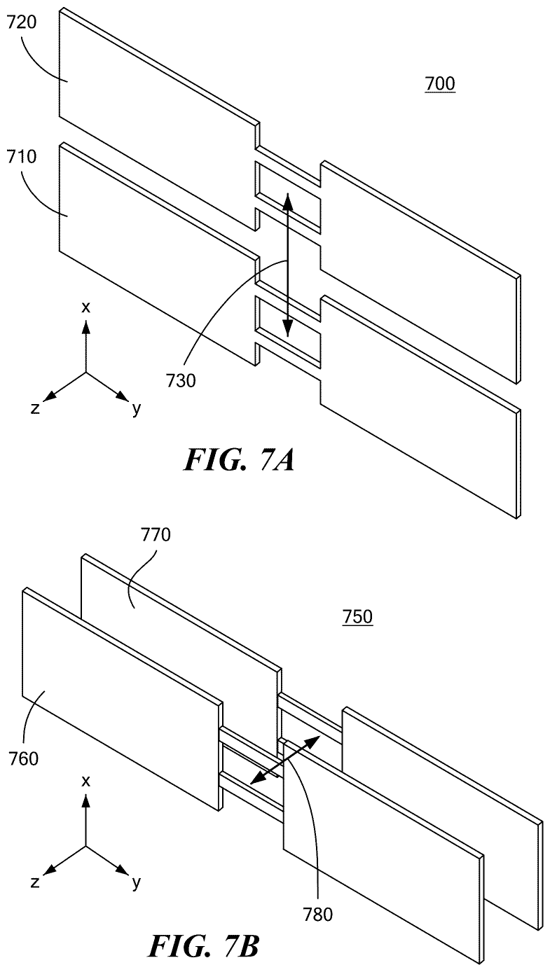

FIG. 7A is a diagram 700 showing an example arrangement of two example conductor structures in a system. Each of conductor structures 710 and 720 may be the same as conductor structure 610, for example. As shown in FIG. 7A, conductor structures 710 and 720 may be positioned such that they are in proximity and adjacent to one another along a plane defined by an X-axis and a Y-axis. That is, conductor structures 710 and 720 may be placed in relation to each other such that a top flat surface of conductor structure 710 is substantially parallel to a top flat surface 720 in an X-Y plane, such that a bottom flat surface of conductor structure 710 is substantially parallel to a bottom flat surface of conductor structure 720 in an X-Y plane, and such that ends of the conductor structures are substantially aligned. Conductor structure 710 and conductor structure 720 may be positioned such that the centers of the holes of the conductor structures are positioned a distance 730 (e.g., a center-to-center distance) from each other. Although only two conductor structures are shown in FIG. 7A, one of skill in the art would recognize that any number of conductor structures may be positioned adjacent to each other in a plane as shown in FIG. 7A. For example, in a three-phase power system utilizing three conductor structures, a third conductor structure may be positioned along the plane defined by the X-axis and the Y-axis, such that a center of a hole of the third conductor structure is positioned a distance 730 from a hole of either conductor structure 710 or conductor structure 720. The arrangement shown in FIG. 7A may be referred to as a “standard vertical slit” arrangement herein.

FIG. 7B is a diagram 750 showing another example arrangement of two example conductor structures in a system. Each of conductor structures 760 and 770 may be the same as conductor structure 610, for example. As shown in FIG. 7B, conductor structures 760 and 770 may be positioned such that they are in proximity and adjacent to one another along a plane defined by an X-axis and Z-axis. That is, conductor structures 760 and 770 may be placed in relation to each other such that a bottom flat surface of conductor structure 760 faces a top flat surface of conductor structure 770, and such that ends of the conductor structures are substantially aligned. Conductor structure 760 and conductor structure 770 may be positioned such that the centers of the holes of the conductor structures are positioned a distance 780 from each other. Although only two conductor structures are shown in FIG. 7B, one of skill in the art would recognize that any number of conductor structures may be positioned adjacent to each other in a plane as shown in FIG. 7B. For example, in a three-phase power system utilizing three conductor structures, a third conductor structure may be positioned along the plane defined by the X-axis and the Z-axis, such that a center of a hole of the third conductor structure is positioned a distance 780 from a hole of either conductor structure 760 or conductor structure 770. The arrangement shown in FIG. 7B may be referred to as a “stacked vertical slit” arrangement herein.

Although not shown in FIG. 7A or 7B, a current sensor device (e.g., current sensor device 650) may be placed in the hole of each respective conductor structure, such that current flowing through each of the conductor structures may be measured by its respective current sensor device. These measurements may then be transmitted to another component or system, such as controller 101 of FIG. 1, which may take actions based on the current measurements. As shown in FIGS. 6A, 7A, and 7B, a conductor structure (e.g., conductor structure 610, conductor structure 710, conductor structure 720, conductor structure 760, conductor structure 770) may have an overall width along a first dimension (e.g., along or in parallel to an X-axis direction) and an overall length along a second dimension (e.g., along or in parallel to a Y-axis direction), where the length along the second dimension is greater than the width along the first dimension.

A possible advantage of using conductor structure(s) 610 in an arrangement as shown in FIG. 7A or 7B is that the conductor structures may be packed relatively closely together. Moreover, as discussed above, placement of current sensor devices in the holes of the conductor structures may mitigate misplacement error in current sensor device measurements.

One potential downside of using conductor structure(s) 610 in an arrangement as shown in FIG. 7A is that magnetic field sensing elements in a current sensor device, when placed in a hole of a conductor structure, may be oriented to sense a magnetic field in a direction facing an adjacent conductor structure (e.g., may be oriented to be sensitive to the magnetic field along the X-axis direction of FIG. 7A). Thus, when a current sensor device is positioned in a hole of a conductor structure and current is flowing in an adjacent conductor structure, the current sensor device may sense the magnetic curl field associated with the current flowing in the adjacent conductor structure. As a result, the current sensor device may attribute this magnetic field strength as being associated with a current in the conductor in which it is positioned, when in fact the sensed magnetic field strength is attributable to a current flowing in the adjacent conductor structure. This error may be referred to as a “crosstalk error” herein. The crosstalk error may result in a current measurement by a current sensor device in such an arrangement to be off by an amount (e.g., 1.5%, 2%) that may depend, for example, on how closely the conductor structures are packed together.

Using conductor structure(s) 610 in the arrangement shown in FIG. 7B may not significantly improve crosstalk error of the system, because when the current sensor device is positioned in a hole of a conductor structure in the arrangement of FIG. 7B, it will still be sensitive to the magnetic curl field caused by any current flowing in an adjacent conductor structure.

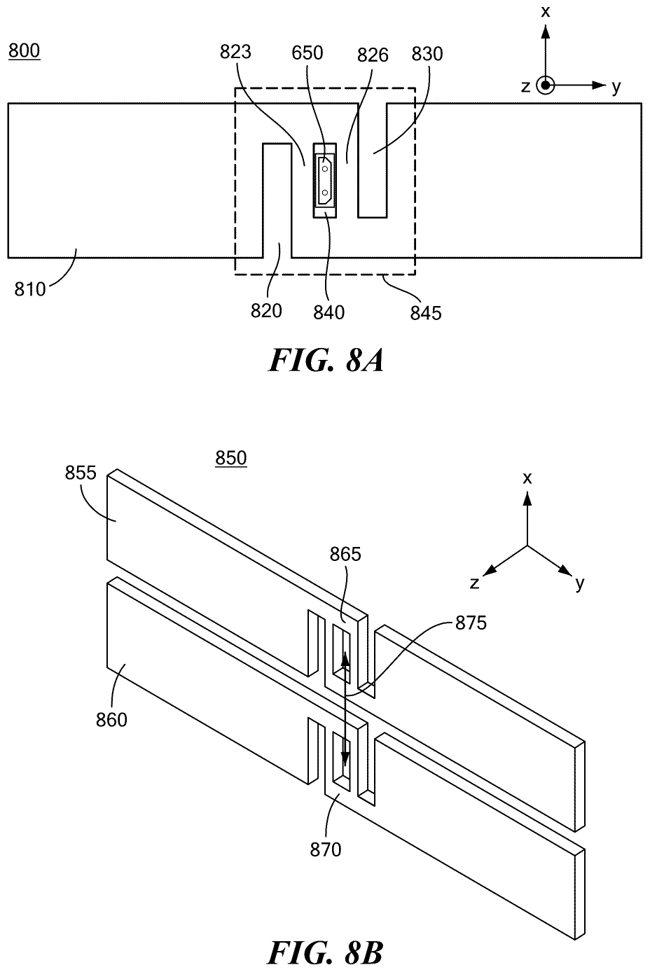

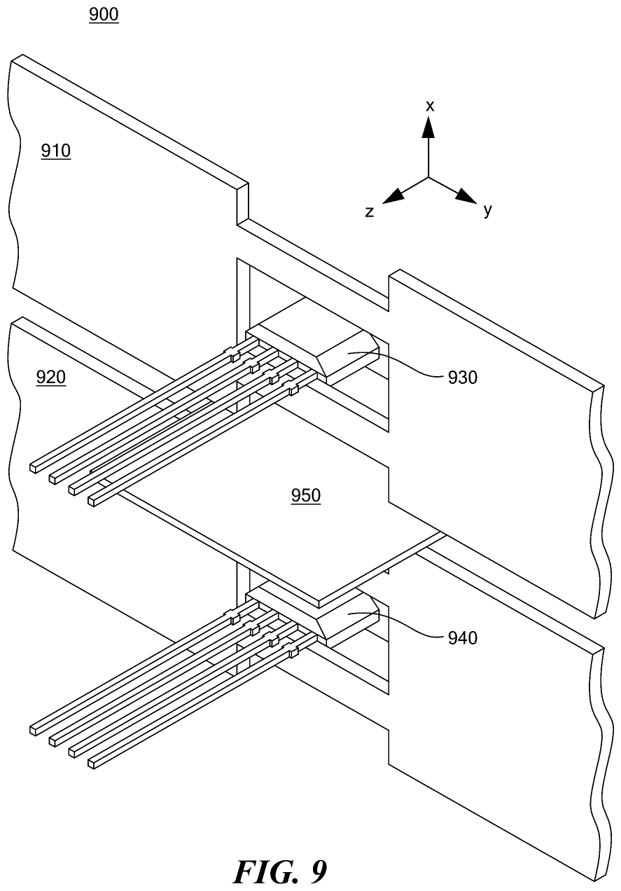

FIG. 8A is a diagram of an example system 800 including another example conductor structure 810 and a current sensor device 650. Example conductor structure 810 may be configured in such a way that it mitigates misplacement error of placing a current sensor device in relation to the conductor structure. Example conductor structure 810 may also be configured such that multiple conductor structures 810 may be placed in close proximity to each other. Example conductor structure 810 may further be configured such that crosstalk error in a system is reduced. That is, in a system using multiple conductor structures 810 placed in proximity with each other, a current sensor device placed in a hole of a first conductor structure may accurately measure an amount of current flowing through the first conductor structure, and may not be very sensitive to the magnetic curl field generated by currents flowing through adjacent conductor structures.

Conductor structure 810 may be a bus bar, and may be capable of carrying a high current, such as currents ranging anywhere from 100 A to over 4,000 A, though the disclosure is not so limited. Conductor structure 810 may be constructed in any of a variety of different shapes, such as flat strips, solid bars, and rods as just some examples. Conductor structure 810 may be composed of copper, brass, aluminum, or any other type of conductive material. Conductor structure 810 may alternatively be formed of a combination of different types of conductive materials, such as in layers. Although not shown in FIG. 8A, conductor structure 810 may include connection points, such as circular voids, for connecting the conductor structure 810 to another component or system, such as a power source (e.g., power source 102), a load (e.g., load 104), or another conductive structure. A conductor structure 810 may be used, for example, for each of conductor structures 108A, 108B, 108C in system 100 of FIG. 1.

Like conductor structure 510, conductive structure 610, conductor structures 710, 720, and conductor structures 760, 770, conductor structure 810 may include a hole 840 in which a current sensor device 650 may be positioned. Current sensor device 650 may be the same as current sensor device 650 of FIGS. 6A-6C, though the disclosure is not so limited. Like the holes in conductor structures 510, 610, 710, 720, 760, and 770, hole 840 may allow a current sensor device to be positioned inside the hole of the conductor structure, thereby reducing the sensitivity of the current sensor device to misplacements of the current sensor device relative to the conductor structure as compared to system 200 of FIG. 2. As previously discussed, although a current sensor device in a TSSOP package may be placed in a hole such as hole 840, it may be desirable to instead utilize a current sensor device in a SIP package for placement in a hole such as hole 840. The current sensor (e.g., current sensor device 650) may be used, for example, for each of current sensor devices 110A, 110B, 110C in system 100 of FIG. 1.

Hole 840 may be turned sidewise (i.e., rotated by 90 degrees) as compared to the holes of conductor structures 510, 610, 710, 720, 760, 770. As a result, a current sensor device (e.g., current sensor device 650) may be rotated by 90 degrees from its orientation in the examples in FIGS. 5A, 6A-6C, 7A, and 7B, and may be placed in hole 840 such that the magnetic field sensing elements (e.g., planar Hall effect elements or Hall plates) of the current sensor device are maximally sensitive to the magnetic field along the Y-axis direction (e.g., the lengthwise direction of the conductor structure). As a result, a current sensor device positioned in hole 840 of conductor structure 810 may not be very sensitive to the magnetic curl field generated by current flowing through an adjacent conductor structure.

Conductor structure 810 may also include a notch 820 formed on one side of conductor structure 810, and a notch 830 formed on the other side of conductor structure 810. In some embodiments, notch 820 and 830 of conductor structure 810 may be formed such that they pass all the way through a thickness of conductor structure 810. As a result of notches 820 and 830 having been formed, two bridges 823, 826 may remain, which may allow current to pass along conductor structure 810. As discussed above with respect to conductor structures 210, 510, 610, 710, 720, 760, 770, bridges 823, 826, being narrower in width than the overall conductive structure, may have a higher current density than in the rest of conductor structure 810, allowing a current sensor device (e.g., current sensor device 650) placed in proximity to bridges 823, 826 to measure current with greater accuracy.

Hole 840, notch 820, and notch 830 may be formed so as to pass through a thickness of conductor structure 810, such as all the way through a thickness of conductor structure 810. As shown in FIG. 8A, a portion 845 of conductor structure 810 including notch 820, hole 840, and notch 830 may have an overall shape that looks similar to the letter “S” and may be referred to as an “S-notch portion.” Conductor structure 810 may be referred to as being an “S-dual bridge” conductor structure herein.

FIG. 8B is a diagram 850 of an arrangement of two example conductor structures 855 and 860 positioned in proximity to one another. For example, each of the conductor structures may be configured as conductor structure 810. Conductor structure 855 may include a portion 865 (e.g., S-notch portion with a hole and two notches) and conductor structure 860 may include a portion 870 (e.g., S-notch portion with a hole and two notches). The center of the holes of the two conductor structures may be positioned apart by a distance 875 (e.g., center-to-center distance).

As shown in FIG. 8B, conductor structures 855 and 860 may be placed in proximity and adjacent to one another along a plane defined by an X-axis and a Y-axis. That is, conductor structures 855 and 860 may be placed in relation to each other such that a top flat surface of conductor structure 855 is parallel to a top flat structure of conductor structure 860 in an X-Y plane, such that a bottom flat surface of conductor structure 855 is parallel to a bottom surface of conductor structure 860 in an X-Y plane, and such that ends of the conductor structures are substantially aligned. Conductor structure 855 and conductor structure 860 may be positioned such that the centers of the holes of the conductor structures are positioned a distance 875 (e.g., a center-to-center distance) from each other. Although only two conductor structures are shown in FIG. 8B, one of skill in the art would recognize that any number of conductor structures may be positioned adjacent to each other in a plane as shown in FIG. 8B. For example, in a three-phase power system utilizing three conductor structures, a third conductor structure (e.g., conductor structure 810) may be positioned along the plane defined by the X-axis and the Y-axis, such that a center of a hole of the third conductor structure is positioned a distance 875 from a hole of either conductor structure 855 or conductor structure 860.

Arranging conductor structures configured as conductor structure 810 in an arrangement 850 may allow the conductor structures to be packed closely together. Moreover, the vertical silt of conductor structure 810 may minimize effects of misplacement of the current sensor device (e.g., current sensor device 650) with respect to conductor structure 810 on the current sensor device's accuracy. The current density of bridges 823, 826 of conductor structure 810 may also improve the accuracy of the current sensor device's measurements. Additionally, when the current sensor device (e.g., current sensor device 650) is placed within hole 840 of conductor structure 810, the magnetic field sensing elements of the current sensor device may be maximally sensitive to the magnetic field along a Y-axis direction, and may therefore have little sensitivity to the magnetic curl field generated by current flowing through an adjacent conductor structure.

FIG. 9 is a diagram of an example system 900 including two example conductor structures 910, 920 positioned in proximity to each other, with an example shield structure 950 positioned between the two conductor structures and example current sensor devices 930, 940 positioned to measure current in each of the conductor structures. As will be further discussed herein, in some embodiments, use of conductor structures, current sensor devices, and a shield structure in an arrangement as shown in system 900 may allow conductor structures to be packed close together, may further reduce crosstalk error as compared to the example arrangements previously discussed, may improve coupling factor as compared to the example arrangements previously discussed, and/or may improve frequency response as compared to the example arrangements previously discussed.

FIG. 9 shows each of conductor structure 910 and conductor structure 920 as being a bus bar. For example, system 900 in FIG. 9 may include a conductor structure 910 and a conductor structure 920 that are each configured as conductor structure 610 (see, e.g., FIGS. 6A, 6B). System 900 may include conductor structure 910 and conductor structure 920 arranged in a standard vertical slit arrangement (see, e.g., FIG. 7A), but with a shield structure 950 positioned between the conductor structures, as shown in FIG. 9. That is, conductor structure 910 and conductor structure 920 may be spaced apart from each other along a first dimension (e.g., direction along or parallel to an X-axis). A current sensor device may be positioned in the hole of each of the conductor structures for measuring current flowing through the respective conductor structure. That is, as shown in FIG. 9, current sensor device 930 may be positioned in a hole in conductor structure 910, and may be configured to measure current flowing through conductor structure 910. Current sensor device 940 may be positioned in a hole in conductor structure 920, and may be configured to measure current flowing through conductor structure 920.

In some embodiments, each of current sensor device 930 and current sensor device 940 may be the same as current sensor device 650 (see, e.g., FIGS. 6A-6C). For example, each of current sensor device 930 and current sensor device 940 may include a SIP package in which the various components (see, e.g., current sensor device 400 of FIG. 4) of the current sensor device may be housed. As discussed above with respect to FIGS. 6A-6C, each of current sensor device 930 and 940 may be oriented in a hole of its respective conductive structure such that the magnetic field sensing elements of the current sensor device are maximally sensitive to a magnetic field along an X-axis direction (e.g., the first dimension) (see FIG. 9). For example, if the magnetic field sensing elements (see, e.g., magnetic field sensing elements 680, 685 of FIG. 6C) of current sensor device 930 are planar Hall effect elements, then when current sensor device 930 is positioned in the hole of conductor structure 910, the sensitive plane of the planar Hall effect elements may face towards the bridges of conductor structure 910. Similarly, if the magnetic field sensing elements of current sensor device 940 are planar Hall effect elements, then when current sensor device 940 is positioned in the hole of conductor structure 920, the sensitive plane of the planar Hall effect elements may face towards the bridges of conductor structure 920.

As previously discussed with respect to FIG. 7A, a potential downside of using conductor structures in a standard vertical slit arrangement is that magnetic field sensing elements in a current sensor device, when placed in a hole of a conductor structure, may sense the magnetic curl field associated with the current flowing in an adjacent conductor structure, resulting in crosstalk error. However, system 900 includes a shield structure 950 positioned between conductor structure 910 and conductor structure 920. As further discussed herein, positioning shield structure 950 between conductor structure 910 and conductor structure 920 may reduce the crosstalk error measured by current sensor device 930 and current sensor device 940. As also discussed herein, positioning shield structure 950 between conductor structure 910 and conductor structure 920 may also improve the coupling factor, gain, and/or frequency response of current sensor devices 930 and 940.

In some embodiments, shield structure 950 may be positioned halfway or approximately halfway between conductor structure 910 and conductor structure 920, though the disclosure is not so limited. In other embodiments, shield structure 950 may be positioned closer to conductor structure than the other conductor structure. In some embodiments, planar surfaces of shield structure 950 are positioned orthogonal to planar surfaces of conductor structure 910 and/or conductor structure 920. For example, if planar surfaces of a conductor structure extend along an X-Y plane (see FIG. 9), shield structure 950 may be positioned such that its planar surfaces extend along a Y-Z plane (see FIG. 9).

In some embodiments, shield structure 950 may be positioned such that a first surface of shield structure 950 faces conductor structure 910, while a second surface of shield structure 950 faces conductor structure 920.

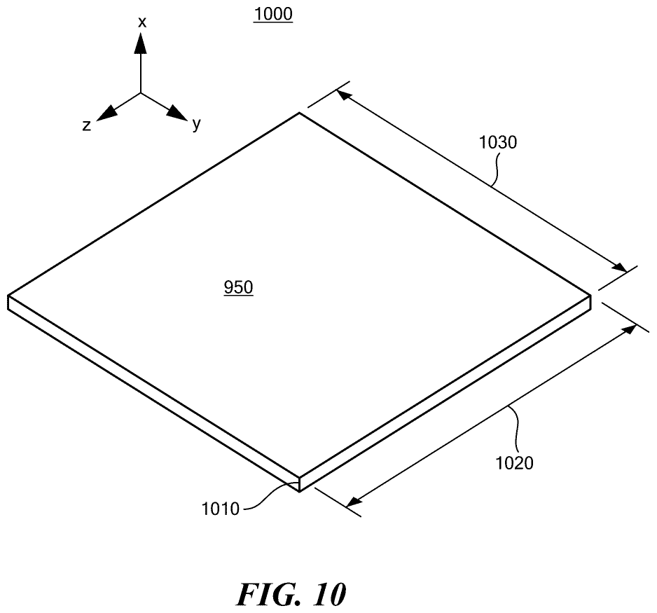

In some embodiments, shield structure 950 may have a height 1020 (see FIG. 10) of at least 5 mm in a second dimension (e.g., along or in parallel to a Z-axis) orthogonal to a first dimension (e.g., along or in parallel to a Y-axis).

In some embodiments, shield structure 950 may be positioned (e.g., along the Z-axis) such that a center of shield structure 950 is aligned with conductor structure 910 and/or conductor structure 920. In some embodiments, shield structure 950 may be positioned (e.g., along the Z-axis) such that a center of shield structure 950 is aligned or approximately aligned with a center conductor structure 910 and/or conductor structure 920 along the Z-axis. In some embodiments, shield structure 950 may be positioned (e.g., along the Y-axis) such that a center of shield structure 950 is aligned with current sensor device 930 and/or current sensor device 940. In some embodiments, shield structure 950 may be positioned (e.g., along the Y-axis) such that a center of shield structure 950 is aligned or approximately aligned with a center of current sensor device 930 and/or current sensor device 940. In some embodiments, shield structure 950 may be positioned (e.g., along the Y-axis) such that a center of shield structure 950 is aligned or approximately aligned with a center of a hole of conductor structure 910 and/or conductor structure 920. In some embodiments, shield structure 950 may be positioned (e.g., along the Y-axis) such that a length (e.g., length 1030) of shield structure 950 extends over a length of the bridges of conductor structure 910 and/or conductor structure 920 along the Y-axis.

Shield structure 950 may be composed of any suitable soft ferromagnetic material. Example materials include, but are not limited to, Silicon Iron (SiFe), Nickel Iron (NiFe), Nickel Iron (NiFe) alloys, ferrite, magnetic stainless steel (e.g., 430F), ferrosilicon, nickel, nickel alloys (e.g., iron nickel, nickel zinc), zinc, zinc alloys, manganese, manganese alloys (e.g., manganese zinc), cobalt, and/or the like. For example, a person of ordinary skill in the art would recognize that a soft ferromagnetic material may generally be a material that has a low coercivity (i.e., easy to demagnetize and does not make a good permanent magnet) as compared to hard ferromagnetic materials that have high coercivity (i.e., does not demagnetize easily), and a high magnetic permeability. The term “coercivity” may generally refer to the intensity of a magnetic field required to de-magnetize a material after it has been magnetized as much as possible. In some embodiments, shield structure 950 may be composed of a combination of different types of materials, some or all of which may include soft ferromagnetic materials.

Shield structure 950 may have a high magnetic permeability. That is, shield structure 950 may be composed of one or more materials having a high magnetic permeability. For example, a person of skill in the art would recognize that different ferromagnetic materials may have different magnetic permeabilities. The term “magnetic permeability” may generally refer to the ability of a material to store or focus magnetic energy, or the degree to which a material becomes magnetized by an applied magnetic field. A material's magnetic permeability may be determined by the way the material's electrons respond to an applied magnetic field. If there are electrons available to line up their spins to reinforce the magnetic field, the material may have a high magnetic permeability and may concentrate the magnetic field. Such materials may include, for example, iron, zinc, and cobalt. Other materials do not have electrons available to line up their spins to reinforce the magnetic field and so have a low magnetic permeability and do not concentrate the magnetic field. Example materials with low magnetic permeability include carbon and oxygen, for example. A value for magnetic permeability of a material may be given as a relative value, with air having a value of 1, and ferrites having relative magnetic permeabilities ranging anywhere from 10 to 10,000. In some embodiments, shield structure 950 may have a magnetic permeability between 4,000 μ and 10,000 μ.

In the example system shown in FIG. 9, shield structure 950 is constructed as a relatively flat plate of soft ferromagnetic material. That is, example shield structure 950 in FIG. 9 is thin and substantially square or rectangular in shape. Example shield structure 950 may be referred to as a “flat shield structure” herein. Although shown as being substantially square or rectangular in shape, the disclosure is not so limited. Example shield structure 950 may have any of a variety of different shapes.

FIG. 10 is a diagram 1000 of example shield structure 950 of FIG. 9. As shown in FIG. 10, shield structure 950 may have a height 1020 along a Z-axis direction, a length 1030 along a Y-axis direction, and a thickness 1010 along an X-axis direction.

In some embodiments, shield structure 950 may have a length 1030 in a range between 5 mm and 40 mm, though the disclosure is not so limited. In some embodiments, shield structure 950 may have a length 1030 in a range between 5 mm and 20 mm, though the disclosure is not so limited. In some embodiments, shield structure 950 may have a length of approximately 10 mm, though the disclosure is not so limited.

In some embodiments, shield structure 950 may have a thickness 1010 in a range between 0.05 mm and 2 mm, though the disclosure is not so limited. In some embodiments, shield structure 950 may have a thickness 1010 in a range between 0.1 mm and 1 mm, though the disclosure is not so limited. In some embodiments, shield structure 950 may have a thickness 1010 of approximately 0.3 mm, though the disclosure is not so limited.

In some embodiments, shield structure 950 may have a height 1020 in a range between 1 mm and 30 mm, though the disclosure is not so limited. In some embodiments, shield structure 950 may have a height 1020 in a range between 5 mm and 15 mm, though the disclosure is not so limited. In some embodiments, shield structure 950 may have a height 1020 of approximately 10 mm, though the disclosure is not so limited. In some embodiments, shield structure 950 may have a height 1020 of approximately 15 mm, though the disclosure is not so limited.

Although example dimensions of shield structure 950 have been provided above, the disclosure is not limited to these dimensions. A person of ordinary skill in the art would recognize that a variety of different dimensions and configurations of a shield structure may be used. Any dimensions and/or configurations of a shield structure that perform substantially the same function in substantially the same way to achieve substantially the same result should be considered to be within the scope of the disclosure herein. For example, one of skill in the art would recognize that dimensions and configurations of a shield structure may be varied if the dimensions of one or more conductor structures (e.g., conductor structure 910, conductor structure 920) was varied, if the distance between the conductor structures was varied, and/or if a different type of current sensor was used. One of skill in the art would also recognize that dimensions and configurations of a shield structure may be varied depending on the needs of a particular application and/or a desired result (e.g., improved crosstalk performance, improved coupling factor, improved gain, improved frequency response). Such variations should be considered to be within the scope of the disclosure herein.

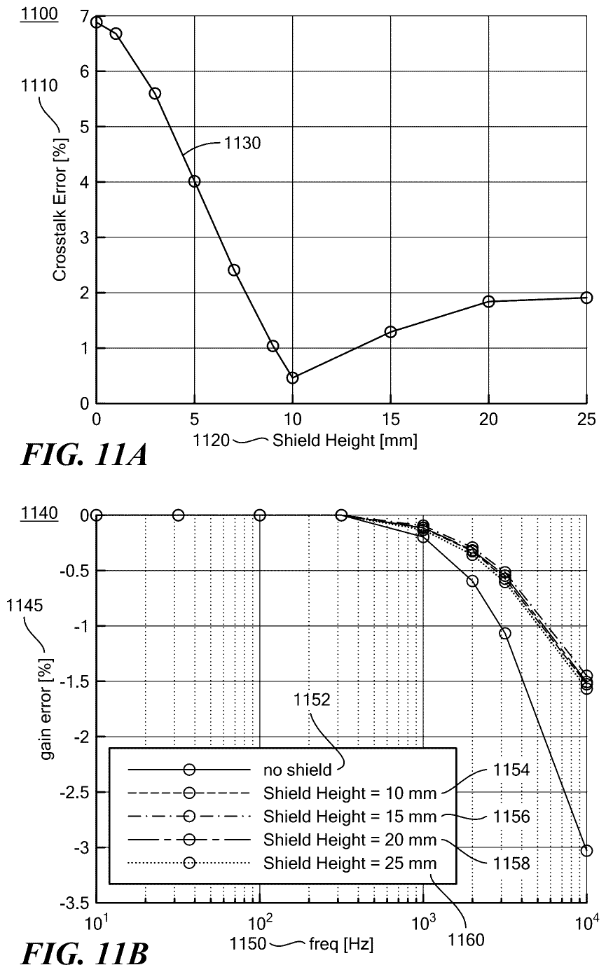

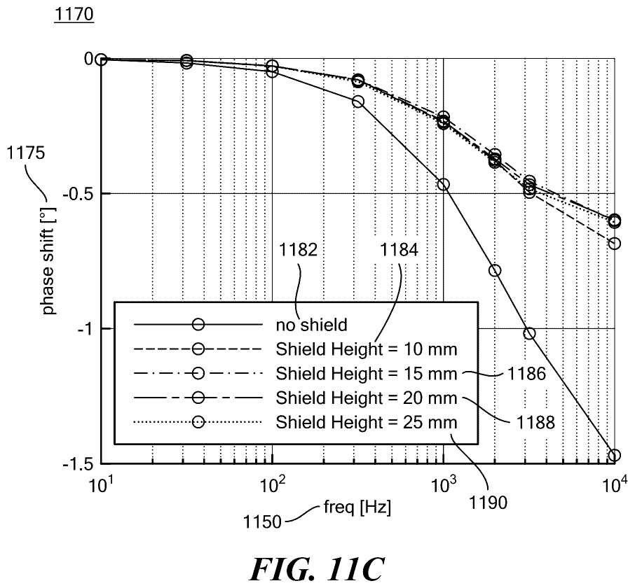

FIG. 11A is a graph 1100 of simulation results, with a plot 1130 representing how cross-talk error varies based on shield structure height in a system using the example conductor structures, current sensor devices, and shield structure in the system of FIG. 9. Graph 1100 includes a Y-axis 1110 representing crosstalk error as a percentage of the current measured by a current sensor device, and an X-axis 1120 representing a height 1020 of shield structure 950 in mm.

Plot 1130 shows that the crosstalk error in the current sensor device is reduced as the shield structure height 1020 gets larger until 10 mm. As a height 1020 of shield structure 950 gets larger than 10 mm, the crosstalk error measured by the current sensor device rises again until it levels off at a height 1020 of approximately 25 mm. Thus, for the specific simulation used to generate graph 1100 based on example system 900, the current sensor device has the lowest crosstalk error when a shield structure with a height 1020 of approximately 10 mm is used.

FIG. 11B is another graph 1140 of simulation results, with plots representing how gain error of a current sensor device varies based on shield structure height and frequency of current flowing in a system using the example conductor structures, current sensor devices, and shield structure of FIG. 9. Graph 1140 includes a Y-axis 1145 representing gain error. For example, gain error represents the percentage change in sensitivity of the current sensor device as a function of the frequency. Graph 1140 also includes an X-axis 1150 representing frequency of the current flowing in the conductor structure.

Plot 1152 shows how the gain error varies over the frequency of the current when no shield structure is used in the simulated system. Plot 1154 shows how the gain error varies over the frequency of the current when a shield structure 950 with a height 1020 of 10 mm is used in the simulated system. Plot 1156 shows how the gain error varies over the frequency of the current when a shield structure 950 with a height 1020 of 15 mm is used in the simulated system. Plot 1158 shows how the gain error varies over the frequency of the current when a shield structure 950 with a height 1020 of 20 mm is used in the simulated system. Plot 1160 shows how the gain error varies over the frequency of the current when a shield structure 950 with a height 1020 of 25 mm is used in the simulated system. As can be seen in graph 1140, for the specific simulation used to generate graph 1140 based on example system 900, the gain error of the current sensor device is reduced when a shield structure 950 with a height 1020 of 10 mm or more is used, as compared to not using a shield structure 950 at all in the system. The amount of gain error of the current sensor device was about the same for shield structures 950 with heights 1020 of 10 mm, 15 mm, 20 mm, and 25 mm.

FIG. 11C is another graph 1170 of simulation results, with plots representing how the phase shift of the current measured by the current sensor device varies based on shield structure height and frequency of current flowing in a system using the example conductor structures, current sensor devices, and shield structure of FIG. 9. Graph 1170 includes a Y-axis 1175 representing phase error. For example, phase error represents a number of degrees by which the current measured by a current sensor device for a conductor structure differs in phase from the phase of the current flowing through the conductor structure. Graph 1170 also includes an X-axis 1150 representing frequency of the current flowing in the conductor structure.

Plot 1182 shows how the phase shift varies over the frequency of the current when no shield structure is used in the simulated system. Plot 1184 shows how the phase shift varies over the frequency of the current when a shield structure 950 with a height 1020 of 10 mm is used in the simulated system. Plot 1186 shows how the phase shift varies over the frequency of the current when a shield structure 950 with a height 1020 of 15 mm is used in the simulated system. Plot 1188 shows how the phase shift varies over the frequency of the current when a shield structure 950 with a height 1020 of 20 mm is used in the simulated system. Plot 1190 shows how the phase shift varies over the frequency of the current when a shield structure 950 with a height 1020 of 25 mm is used in the simulated system. Thus, for the specific simulation used to generate graph 1170 based on example system 900, the phase shift between the current measured by the current sensor device and the current flowing through the conductor structure is reduced when a shield structure 950 with a height 1020 of 10 mm or more is used, as compared to not using a shield structure at all in the system. The amount of phase shift between the current measured by the current sensor device and the current flowing through the conductor structure was about the same for shield structures 950 with heights 1020 of 10 mm, 15 mm, 20 mm, and 25 mm.

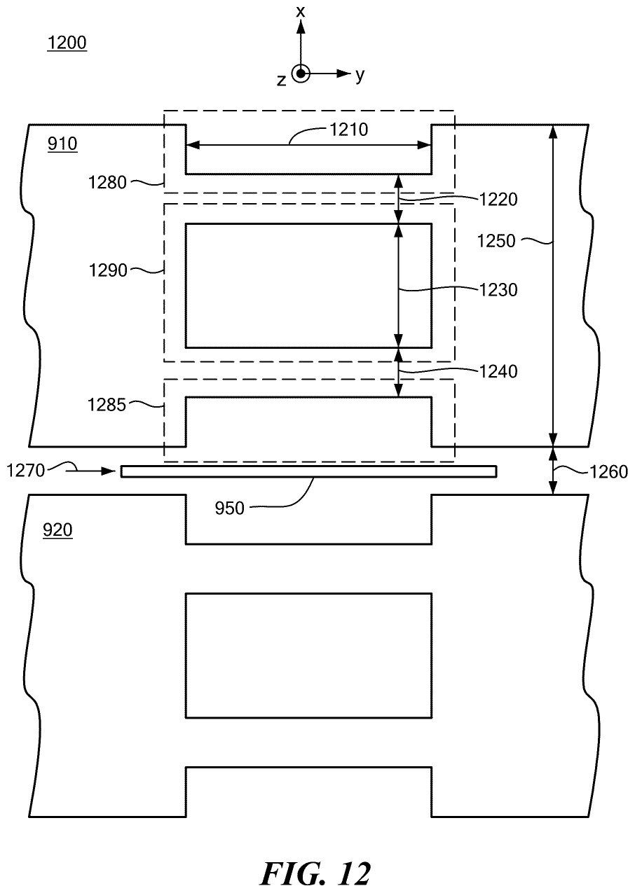

FIG. 12 is a diagram of an example system 1200 including the two example conductor structures 910, 920 of FIG. 9 positioned in proximity to each other, with the example shield structure 950 of FIG. 9 positioned between the two conductor structures, when viewed from another perspective (i.e., along the Z-axis).

As shown in FIG. 12, a conductor structure (e.g., conductor structure 910, 920) may have a first portion 1290 that defines a hole (e.g., hole 625) in the conductor structure, a second portion 1280 that defines a first notch (e.g., notch 616) out of a first side of the conductor structure, and a third portion 1285 that defines a second notch (e.g., notch 613) out of a second side of the conductor structure.

A conductor structure (e.g., conductor structure 910, 920) may have an overall width 1250 along a first dimension (e.g., direction along or parallel to an X-axis). For example, width 1250 may be a width in a range between 10 mm and 25 mm (e.g., 18 mm), though the disclosure is not so limited.

The conductor structure (e.g., conductor structure 910, 920) may have a length 1210 of a notch (e.g., notch 613, 616) and/or hole (e.g., hole 625) along a second dimension (e.g., direction along or parallel to a Y-axis). For example, length 1210 may be a length in a range between 5 mm and 15 mm (e.g., 10 mm), though the disclosure is not so limited.

The conductor structure (e.g., conductor structure 910, 920) may have a width 1230 of the hole (e.g., hole 625) along the first dimension (e.g., direction along or parallel to the X-axis). For example, width 1230 may be a width in a range between 2 mm and 8 mm (e.g., 5 mm), though the disclosure is not so limited.

The conductor structure (e.g., conductor structure 910, 920) may have a width 1220 of a first bridge (e.g., bridge 620) and a width 1240 of a second bridge (e.g., bridge 620) along the first dimension (e.g., direction along or parallel to the X-axis). In some embodiments, width 1220 and width 1240 may be the same. In some embodiments, width 1220 and width 1240 may be different. For example, width 1220 and/or width 1240 may be a width in a range between 1 mm and 5 mm (e.g., 2 mm), though the disclosure is not so limited.

The conductor structure (e.g., conductor structure 910, 920) may have a thickness (not shown in FIG. 12) along a third dimension (e.g., direction along or parallel to the Z-axis). In some embodiments, when the conductor structure is a busbar, the thickness may be a thickness in a range between 1 mm and 5 mm (e.g., 2 mm), though the disclosure is not so limited. In some embodiments, when the conductor structure is one or more traces (e.g., copper traces) on a PCB, the thickness may be a thickness in a range between 0.1 mm and 0.07 mm.

Shield structure 950 may have a thickness 1270 along the first dimension (e.g., direction along or parallel to the X-axis). For example, thickness 1270 may be a thickness in a range between 0.1 mm and 1 mm (e.g., 0.3 mm), though the disclosure is not so limited.

The conductor structures (e.g., conductor structures 910, 920) may be placed apart from each other by a distance 1260 along the first dimension (e.g., direction along or parallel to the X-axis). For example, distance 1260 may be a distance in a range between 0.2 mm and 30 mm (e.g., 1 mm, 2 mm, 3 mm), though the disclosure is not so limited.

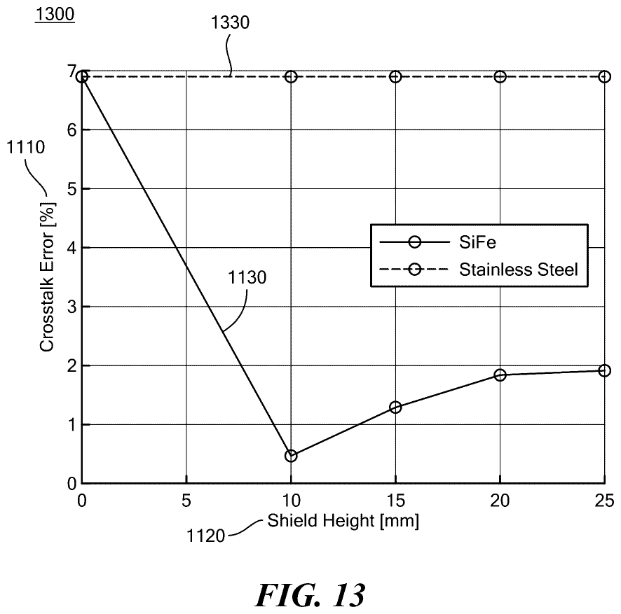

For the simulations of system 900 resulting in the graphs of FIGS. 11A-11C and FIG. 13, overall width 1250 was set at 16 mm, length 1210 was set at 10 mm, widths 1220 and 1240 were set at 2 mm, width 1230 was set at 5 mm, thickness of the conductor structures was set at 2 mm, thickness 1270 was set at 0.5 mm, distance 1260 was set at 2 mm, and shield structure 950 was composed of SiFe.

FIG. 13 is a graph 1300 of simulation results, with plots representing how crosstalk error varies based on shield structure height and material used in the shield structure in a system using the example conductor structures, current sensor devices, and shield structure of FIG. 9. Graph 1300 includes a Y-axis 1110 representing crosstalk error as a percentage of the current measured by a current sensor device, and an X-axis 1120 representing a height 1020 of shield structure 950 in mm.

Plot 1330 shows, when shield 950 is constructed of a non-magnetic stainless steel, crosstalk error in the current sensor device does not improve regardless of shield structure height 1020. That is, when shield structure 950 is constructed of a non-magnetic stainless steel, the crosstalk error in the current sensor device is approximately 7% for any shield structure height 1020 greater than 0 mm up to 25 mm.

Plot 1130 is the same as plot 1130 of FIG. 11A and shows that, when shield structure 950 is constructed of the ferromagnetic material SiFe, crosstalk error in the current sensor device is reduced as shield structure height 1020 gets larger until 10 mm. As a height 1020 of shield structure 950 constructed of SiFe gets larger than 10 mm, the crosstalk error measured by the current sensor device rises again until it levels off at a height 1020 of approximately 25 mm. However, plot 1130 shows that, at any height 1020 of shield structure 950 greater than 0 mm up to 25 mm, use of the ferromagnetic SiFe shield structure improves crosstalk error as compared to not using a shield structure or as compared to using a non-magnetic stainless steel shield structure.

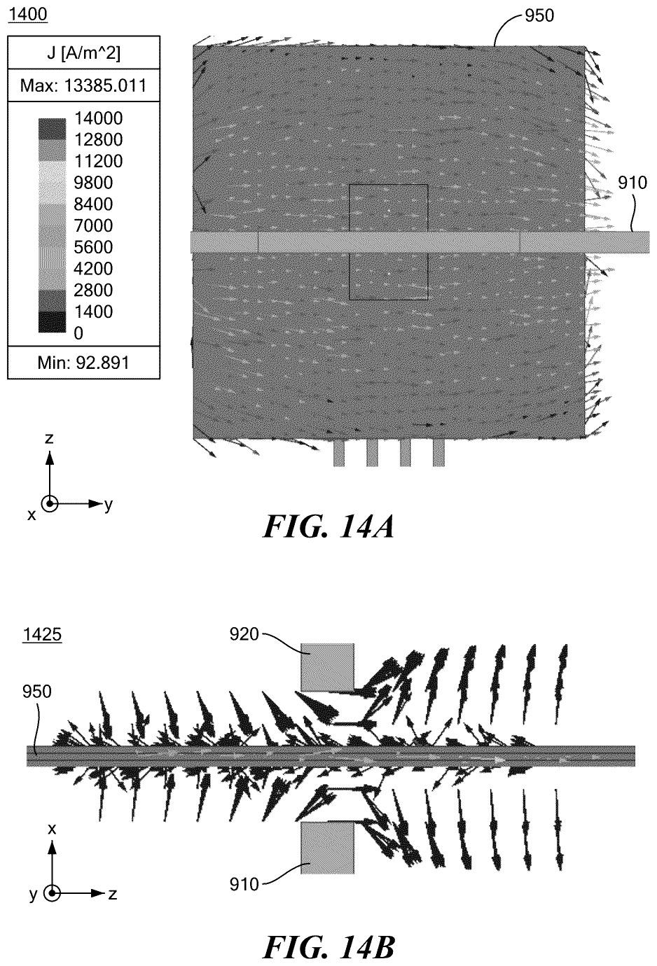

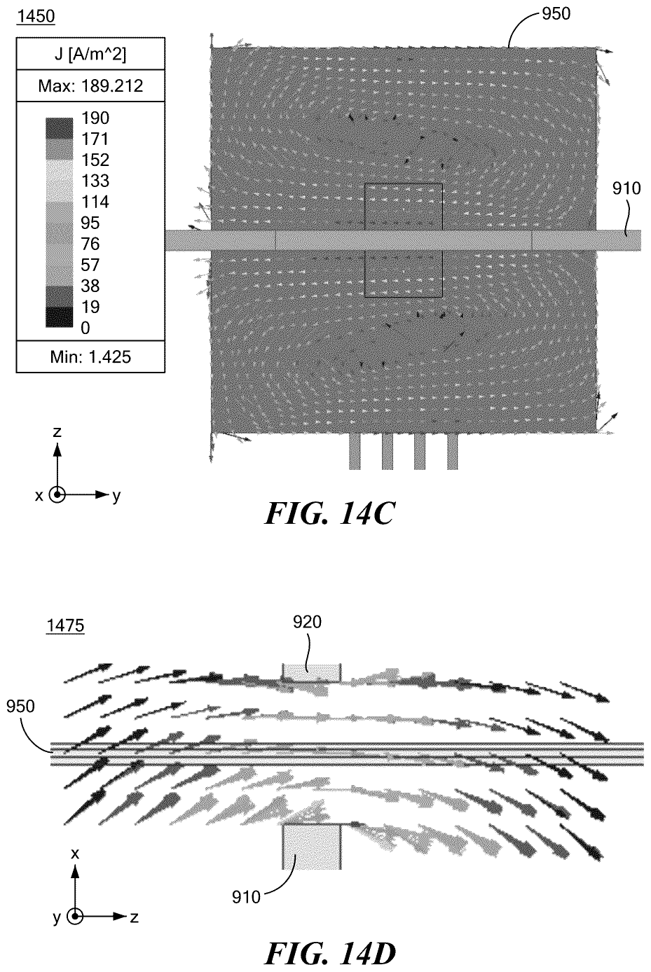

FIGS. 14A and 14B are graphs 1400 and 1425, respectively, of simulation results, with plots of vectors representing a magnetic field around an example conductor structure (e.g., conductor structure 910) and shield structure (e.g., shield structure 950) as shown in FIG. 9. For example, graph 1400 represents the magnetic curl field generated by current flowing through a conductor structure 910, and shows conductor structure 910 and shield structure 950, as viewed along the X-axis, where shield structure 950 is constructed of a ferromagnetic material SiFe. Graph 1425 represents the magnetic curl field generated by a current flowing through conductor structure 910 around conductor structure 910 and shield structure 950, viewed along the Y-axis, where shield structure 950 is constructed of SiFe.

FIGS. 14C and 14D are graphs 1450 and 1475, respectively, of simulation results, with plots of vectors representing a magnetic field around an example conductor structure (e.g., conductor structure 910) and shield structure (e.g., shield structure 950) as shown in FIG. 9. For example, graph 1450 represents the magnetic curl field generated by current flowing through a conductor structure 910, and shows conductor structure 910 and shield structure 950, as viewed along the X-axis, where shield structure 950 is constructed of a non-magnetic stainless steel. Graph 1475 represents the magnetic curl field generated by a current flowing through conductor structure 910, viewed along the Y-axis, where shield structure 950 is constructed of a non-magnetic stainless steel. As can be seen from graph 1475, the magnetic field vectors are not affected by the non-magnetic stainless steel shield structure.

As can be seen by comparing FIGS. 14A and 14B with FIGS. 14C and 14D, a shield structure 950 made of a ferromagnetic material may change the orientation of the magnetic field vectors as compared to a non-ferromagnetic (e.g., stainless steel) shield, improving coupling factor.

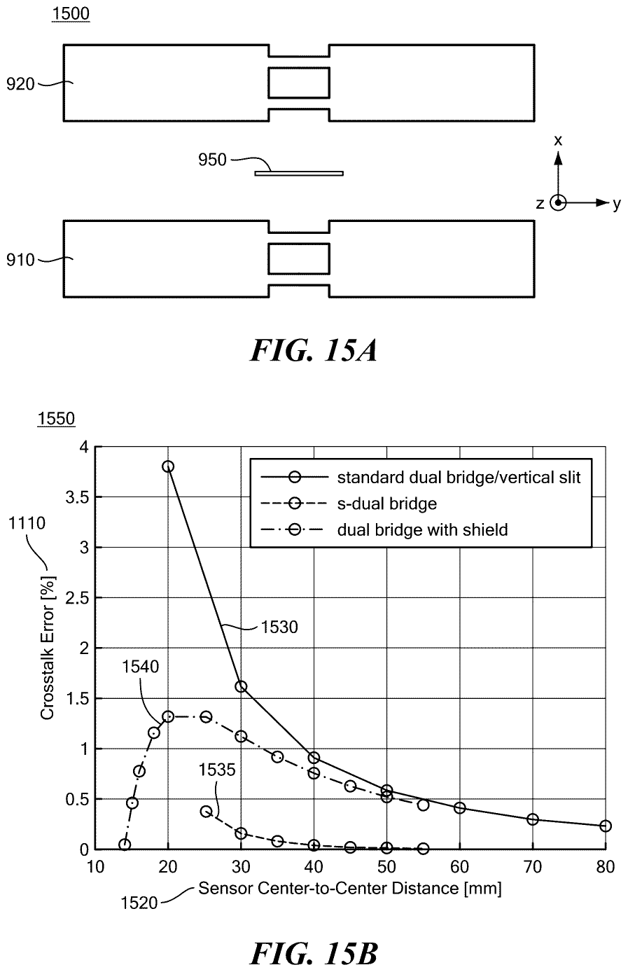

FIG. 15A is a diagram 1500 corresponding to the example system of FIGS. 9 and 12, where shield structure 950 is positioned approximately halfway between the conductor structures (e.g., conductor structure 910, conductor structure 920).

FIG. 15B is a graph 1550 of simulation results, including plots representing how crosstalk error varies for a current sensor device measuring current flowing in a conductor structure in an arrangement of conductor structures, based on a center-to-center distance between current sensor devices in the arrangement, based on the type of conductor structure in the arrangement, and based on whether a shield structure is positioned halfway between the conductor structures. Graph 1550 includes a Y-axis 1110 representing crosstalk error as a percentage of the current measured by a current sensor device, and an X-axis 1520 representing a center-to-center distance between current sensor devices in the arrangement, in mm.

Plot 1530 shows the crosstalk error in a current sensor device in an arrangement of “dual bridge” (or “vertical slit”) conductor structures (see, e.g., FIG. 6A, FIG. 7A, FIG. 7B), where no shield structure is used and where the center-to-center distance between current sensor devices in the holes of the dual bridge conductors is varied. As can be seen from plot 1530, as the sensor center-to-center distance increases (i.e., as the conductor structures are positioned further apart), the crosstalk error is reduced. As the sensor center-to-center distance decreases to less than 20 mm, the crosstalk error becomes greater than 4%.

Plot 1535 shows the crosstalk error in a current sensor device in an arrangement of “S-dual bridge” conductor structures (see, e.g., FIG. 8A, FIG. 8B), where no shield is used and where the center-to-center distance between current sensor devices in the holes of the S-dual bridge conductor structures is varied. As can be seen from plot 1535, as the sensor center-to-center distance increases (i.e., as the conductor structures are positioned further apart), the crosstalk error is reduced. Plot 1535 does not extend to sensor center-to-center distances of less than about 25 mm, because the centers of the current sensor devices cannot be placed any closer, due to the current sensor devices being rotated by 90 degrees in their placement in these conductor structures (see, e.g., FIG. 8A, FIG. 8B) as compared to their placement in the “dual bridge” conductor structures (see, e.g., FIGS. 6A-6C, FIG. 9).

Plot 1540 shows the crosstalk error in a current sensor device in an arrangement of “dual bridge” (or “vertical slit”) conductor structures where a soft ferromagnetic (e.g., SiFe) shield structure is used (see, e.g., FIG. 9, FIG. 12) and where the shield structure is positioned halfway between the conductor structures. As can be seen from plot 1540, as the sensor center-to-center distance decreases down to about 15 mm or less, the crosstalk error is reduced to nearly 0%. As the sensor center-to-center distance increases (i.e., as the conductor structures are positioned further apart), the crosstalk error increases until about the sensor center-to-center distance is about 20 mm, and then decreases as the sensor center-to-center distance increases above 20 mm. For the simulation resulting in graph 1550, the first, second, and third points of plot 1540 corresponded to an edge-to-edge distance between the conductor structures of 1 mm, 2 mm, and 3 mm, respectively.

Thus, as shown in graph 1550, arrangements using a soft ferromagnetic shield structure positioned halfway between dual bridge conductor structures (see, e.g., FIG. 9, FIG. 12, FIG. 15A) improve crosstalk error over arrangements using just dual bridge conductor structures with no shield structure (see, e.g., FIG. 7A, FIG. 7B). As also shown in graph 1550, arrangements using a soft ferromagnetic shield structure positioned halfway between dual bridge conductor structures (see, e.g., FIG. 9, FIG. 12, FIG. 15A) improves crosstalk error over arrangements using S-dual bridge conductor structures, when the sensor center-to-center distance of the current sensor devices in the dual bridge conductor structures are positioned at less than about 15 mm. That is, arrangements of dual bridge conductor structures, when arranged with a soft ferromagnetic shield structure between them, may be packed even closer together than arrangements of S-dual bridge conductor structures, and with improved crosstalk error.

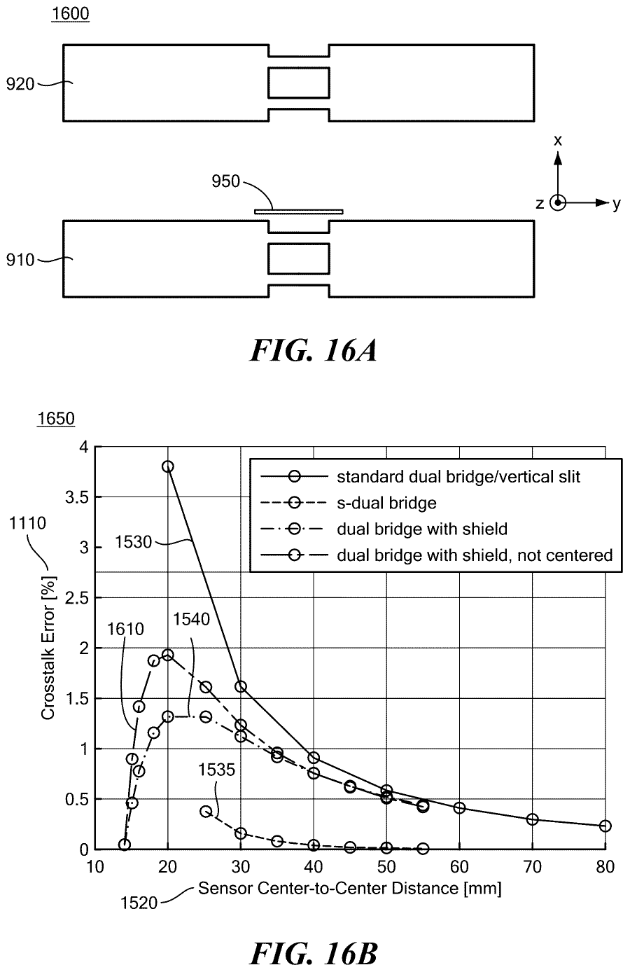

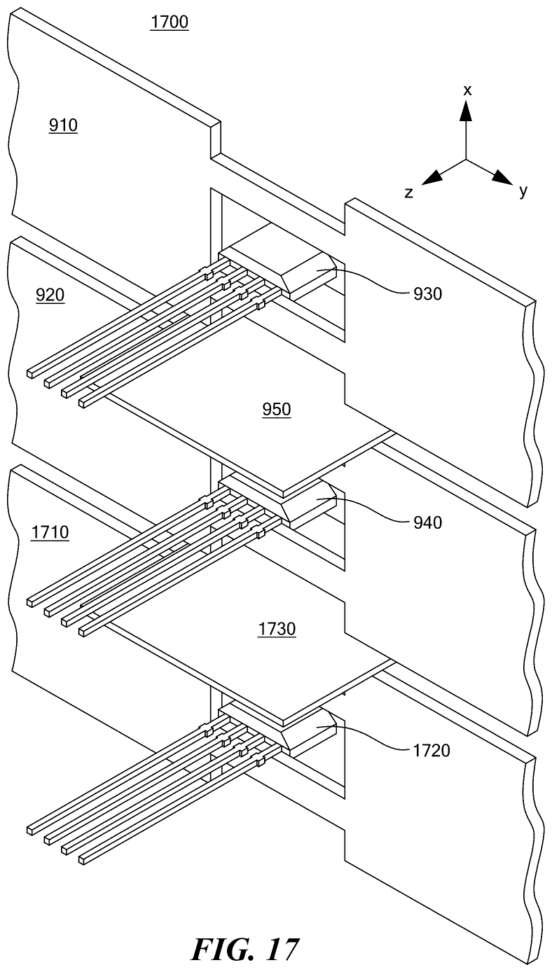

FIG. 16A is a diagram 1600 corresponding to the example system of FIGS. 9 and 12, where shield structure 950 is positioned closer to one of the conductor structures (e.g., conductor structure 910) than another of the conductor structures (e.g., conductor structure 920).

FIG. 16B is a graph 1650 of simulation results, including plots representing how crosstalk error varies for a current sensor device measuring current flowing in a conductor structure in an arrangement of conductor structures, based on a center-to-center distance between current sensor devices in the arrangement, based on the type of conductor structure in the arrangement, and based on whether a shield structure is positioned halfway between the conductor structures or is positioned closer to one of the conductor structures than another of the conductor structures. Graph 1650 includes a Y-axis 1110 representing crosstalk error as a percentage of the current measured by a current sensor device, and an X-axis 1520 representing a center-to-center distance between current sensor devices in the arrangement, in mm.

Plots 1530, 1535, and 1540 are the same as plots 1530, 1535, and 1540 of graph 1550 in FIG. 15B. Plot 1610 shows the crosstalk error in a current sensor device in an arrangement of “dual bridge” (or “vertical slit”) conductor structures where a soft ferromagnetic (e.g., SiFe) shield structure is used (see, e.g., FIG. 9, FIG. 12) and where the shield structure is positioned closer to one of the conductor structures than another of the conductor structures (see, e.g., FIG. 16A). As can be seen from plot 1610, as the sensor center-to-center distance decreases down to about 15 mm or less, the crosstalk error is reduced to nearly 0%. As the sensor center-to-center distance increases (i.e., as the conductor structures are positioned further apart), the crosstalk error increases at a faster rate than it does for arrangements where the shield structure is positioned halfway between the conductor structures (see plot 1540), until the sensor center-to-center distance is about 20 mm, and then decreases as the sensor center-to-center distance increases above 20 mm.

Thus, as shown in graph 1650, crosstalk error is improved when the shield structure is positioned halfway between the adjacent conductor structures as compared to when the shield structure is positioned closer to one of the conductor structures than the adjacent conductor structure.

FIG. 17 is a diagram of an example system 1700 including three example conductor structures 910, 920, 1710 positioned in proximity to each other, with example shield structures 950, 1730 positioned between the conductor structures and example current sensor devices 930, 940, 1720 positioned to measure current in each of the conductor structures. For example, current sensor device 930 is positioned to measure current in conductor structure 910, current sensor device 940 is positioned to measure current in conductor structure 920, and current sensor device 1720 is positioned to measure current in conductor structure 1710. As shown in FIG. 17, system 1700 may include soft ferromagnetic shield structures positioned adjacent to conductor structures. For example, shield structure 950 is positioned between conductor structure 910 and conductor structure 920, and shield structure 1730 is positioned between conductor structure 920 and conductor structure 1710.

System 1700 may be a system of conductor structures, shield structures, and current sensor devices for use in a three-phase power system. In some embodiments, conductor structures 910, 920, 1710 may correspond to conductor structures 108A, 108B, 108C of FIG. 1, and current sensor devices 930, 940, 1720 may correspond to current sensor devices 110A, 110B, 110C of FIG. 1. As previously discussed, current sensor devices 930, 940, 1720 may be coupled via their pins to wires and/or PCBs, which may be further coupled to a controller (e.g., ECU), such as controller 101 of system 100 of FIG. 1. The controller may use the current measurements received from the current sensor devices to control a power source (e.g., power source 102) and/or load (e.g., load 104). As previously discussed, the disclosure herein should not be limited to a three-phase power system. As just one example, a six-phase power system may be implemented using six adjacent conductor structures, five shield structures, and six current sensor devices.

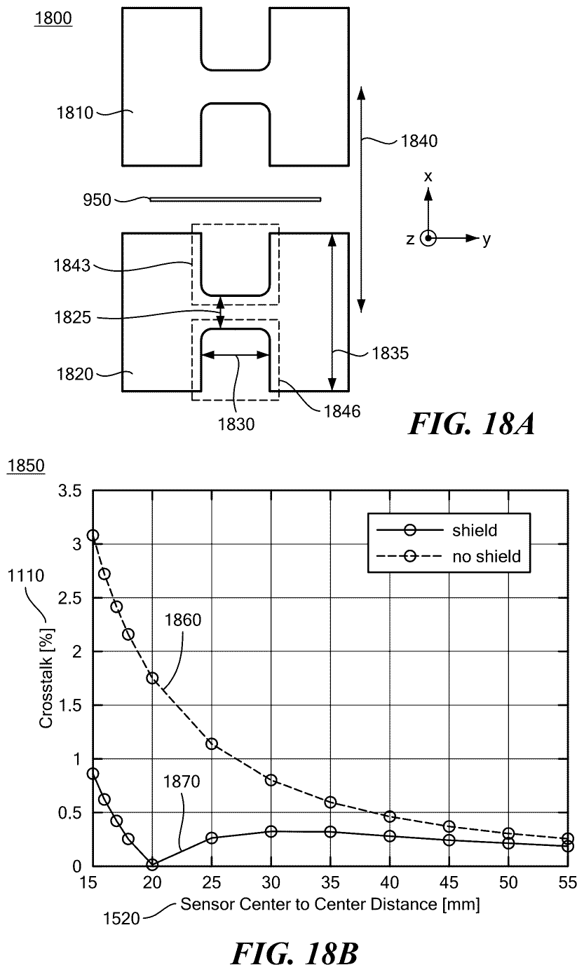

FIG. 18A is a diagram of another example system 1800 including two example conductor structures 1810, 1820 positioned in proximity to each other, with an example soft ferromagnetic shield structure 950 positioned between the two conductor structures. FIG. 18A shows portions of conductor structures 1810, 1820, where notches on either side of the conductor structures form a bridge. For example, conductor structure 1810 and conductor structure 1820 may be the same as conductor structure 210 of FIG. 2. A respective current sensor device (not shown in FIG. 18A) (e.g., current sensor device 250, current sensor device 650) may be positioned above or below the bridge of each of the conductor structures, as previously discussed with respect to FIG. 2.

As shown in FIG. 18A, a conductor structure (e.g., conductor structure 1810, 1820) may include a first portion 1843 that forms a first notch (e.g., notch 220) out of a first side of the conductor structure and a second portion 1846 that forms a second notch (e.g., notch 230) out of a second side of the conductor structure, leaving a bridge portion 240 between the notches.

A conductor structure (e.g., conductor structure 1810, 1820) may have an overall width 1835 along a first dimension (e.g., direction along or parallel to an X-axis). For example, width 1835 may be a width in a range between 10 mm and 25 mm (e.g., 18 mm), though the disclosure is not so limited.

The conductor structure (e.g., conductor structure 1810, 1820) may have length 1830 of a notch (e.g., notch 220, 230) along a second dimension (e.g., direction along or parallel to a Y-axis). For example, length 1830 may be a length in a range between 3 mm and 15 mm (e.g., 6 mm), though the disclosure is not so limited.

The conductor structure (e.g., conductor structure 1810, 1820) may have a width 1825 of a bridge portion (e.g., bridge portion 240) along the first dimension (e.g., direction along or parallel to the X-axis). For example, width 1825 may be a width in a range between 1 mm and 10 mm (e.g., 3 mm), though the disclosure is not so limited.

The conductor structures (e.g., conductor structures 1810, 1820) may have a center-to-center distance 1840 along the first dimension (e.g., direction along or parallel to the X-axis). For example, distance 1840 may be a distance in a range between 10 mm and 50 mm (e.g., 20 mm), though the disclosure is not so limited.

For the simulations of system 1800 resulting in graph 1850 of FIG. 18B, overall width 1835 was set at 14 mm, length 1830 was set at 6 mm, width 1825 was set at 3 mm, distance 1840 (i.e., sensor center-to-center distance) was varied, and the shield structure (e.g., shield structure 950) was an SiFe shield structure with dimensions of a height 1020 of 15 mm, a length 1030 of 15 mm, and a thickness of 0.3 mm.

FIG. 18B is a graph 1850 of simulation results of a simulated current sensor in the arrangement of system 1800. The simulation results represent how crosstalk error varies based on whether a shield structure is positioned halfway between the conductor structures (e.g., conductor structure 1810, conductor structure 1820) and based on a center-to-center distance between simulated current sensor devices in the system. Graph 1850 includes a Y-axis 1110 representing crosstalk error as a percentage of the current measured by a current sensor device, and an X-axis 1520 representing a center-to-center distance between current sensor devices in the system, in mm.

Plot 1860 shows that the crosstalk error in system 1800 when a shield structure is not used is reduced as the center-to-center distance is increased (i.e., as conductor structure 1810 and conductor structure 1820 are moved apart).

Plot 1870 shows that, in system 1800, when a shield structure 950 (e.g., SiFe shield structure) is positioned halfway between the conductor structures, the crosstalk error is reduced at every center-to-center distance as compared to the system when a shield structure is not used (see plot 1860). As shown by plot 1870, the crosstalk error reduces as the center-to-center distance increases until a sensor center-to-center distance of approximately 20 mm. As the sensor center-to-center distance increases from 20 mm, the crosstalk error increases, but is still smaller than in the system that does not use the shield structure (see plot 1860).

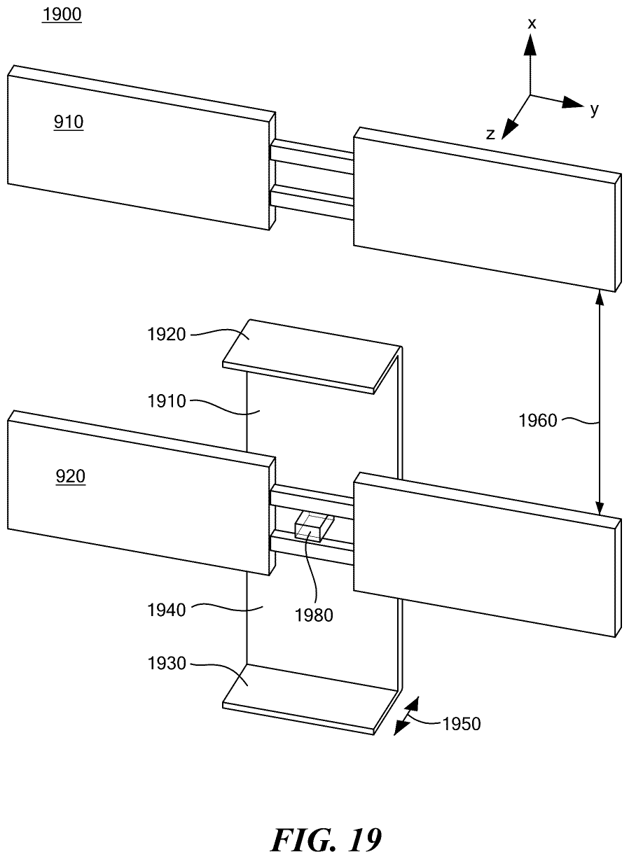

FIG. 19 is a diagram of an example system 1900 including two example conductor structures 910, 920 positioned in proximity to each other, with another example shield structure 1910 positioned between the two conductor structures. In some embodiments, conductor structure 910 and/or conductor structure 920 may be a dual bridge conductor (see, e.g., FIGS. 6A, 6B, 7A, 7B, 9, 12, 15A, 16A, 17), though the disclosure is not so limited. An example current sensor device 1980 is shown positioned to measure current in conductor structure 920. Current sensor device 1980 may be, for example, a current sensor device in a SIP package or TSSOP package as previously discussed. In some embodiments, current sensor device 1980 may be the same as current sensor device 250, current sensor device 400, current sensor device 505, current sensor device 555, current sensor device 650, current sensor device 930, current sensor device 940, or current sensor device 1720, though the disclosure is not so limited. Another current sensor device (not shown) may be positioned in the hole of conductor structure 910.

Shield structure 1910 may be composed of any suitable soft ferromagnetic material. Example materials include, but are not limited to, Silicon Iron (SiFe), Nickel Iron (NiFe), Nickel Iron (NiFe) alloys, ferrite, magnetic stainless steel (e.g., 430F), ferrosilicon, nickel, nickel alloys (e.g., iron nickel, nickel zinc), zinc, zinc alloys, manganese, manganese alloys (e.g., manganese zinc), cobalt, and/or the like. For example, a person of ordinary skill in the art would recognize that a soft ferromagnetic material may generally be a material that has a low coercivity (i.e., easy to demagnetize and does not make a good permanent magnet) as compared to hard ferromagnetic materials that have high coercivity (i.e., does not demagnetize easily), and that has a high magnetic permeability. The term “coercivity” may generally refer to the intensity of a magnetic field required to de-magnetize a material after it has been magnetized as much as possible. In some embodiments, shield structure 1910 may be composed of a combination of different types of materials, some or all of which include soft ferromagnetic materials.

Shield structure 1910 may have a high magnetic permeability. That is, shield structure 1910 may be composed of one or more materials having a high magnetic permeability. For example, a person of skill in the art would recognize that different ferromagnetic materials may have different magnetic permeabilities. The term “magnetic permeability” may generally refer to the ability of a material to store or focus magnetic energy, or the degree to which a material becomes magnetized by an applied magnetic field. A material's magnetic permeability may be determined by the way the material's electrons respond to an applied magnetic field. If there are electrons available to line up their spins to reinforce the magnetic field, the material may have a high magnetic permeability and may concentrate the magnetic field. Such materials may include, for example, iron, zinc, and cobalt. In some embodiments, shield structure 1910 may have a magnetic permeability between 4,000μ and 10,000 μ.

In the example system shown in FIG. 19, shield structure 1910 is constructed as a relatively flat plate of soft ferromagnetic material with two 90 degree bends in the material forming two edges 1920, 1930. One or more of the edges may have a height 1950. A height of the edges may be the same or may be different. A connector portion 1940 may connect the two edges. As can be seen from FIG. 19, shield structure 1910 may be shaped like the letter “U.” Example shield structure 1910 may be referred to as a “U-shaped shield” herein. Although shown in FIG. 19 as being shaped like the letter “U,” the disclosure is not so limited. A shield structure (e.g., shield structure 1910) may have any of a variety of different shapes, such as a shape like the letter “C” as just one example.

Conductor structure 910 and conductor structure 920 may be positioned apart by a distance 1960. In some embodiments, edge 1920 of shield structure 1910 may be positioned halfway or approximately halfway between conductor structure 910 and conductor structure 920, though the disclosure is not so limited. In some embodiments, edge 1920 of shield structure 1910 may be positioned closer to one conductor structure than the other conductor structure. In some embodiments, planar surfaces of edge 1920 of shield structure 1910 are positioned orthogonal to planar surfaces of conductor structure 910 and/or conductor structure 920. For example, if planar surfaces of a conductor structure extend along an X-Y plane (see FIG. 19), edge 1920 of shield structure 1910 may be positioned such that its planar surfaces extend along a Y-Z plane (see FIG. 19).

In some embodiments, edge 1920 of shield structure 1910 may be positioned such that a first surface of edge 1920 of shield structure 1910 faces conductor structure 910, while a second surface of edge 1920 of shield structure 1910 faces conductor structure 920.

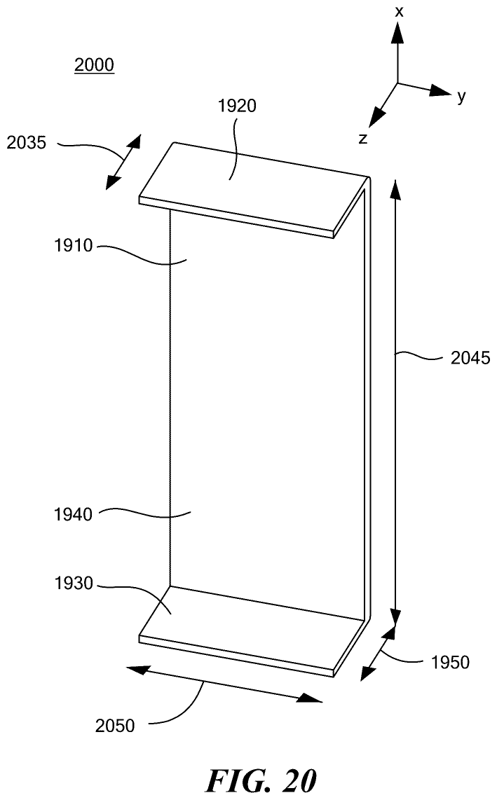

In some embodiments, edge 1920 of shield structure 1910 may have a height 2035 (see FIG. 20) of at least 10 mm in a second dimension (e.g., along or in parallel to a Z-axis) orthogonal to a first dimension (e.g., along or in parallel to a Y-axis).

In some embodiments, edge 1920 of shield structure 1910 may be positioned (e.g., along the Z-axis) such that a center of edge 1920 of shield structure 1910 is aligned with conductor structure 910 and/or conductor structure 920. In some embodiments, edge 1920 of shield structure 1910 may be positioned (e.g., along the Z-axis) such that a center of edge 1920 of shield structure 950 is aligned or approximately aligned with a center of conductor structure 910 and/or conductor structure 920 along the Z-axis. In some embodiments, edge 1920 of shield structure 1910 may be positioned (e.g., along the Y-axis) such that a center of edge 1920 of shield structure 1910 is aligned with current sensor device 1980 and/or a current sensor device positioned in the hole of conductor structure 910. In some embodiments, edge 1920 of shield structure 1910 may be positioned (e.g., along the Y-axis) such that a center of edge 1920 of shield structure 1910 is aligned or approximately aligned with a center of current sensor device 1980 and/or a current sensor device positioned in the hole of conductor structure 910. In some embodiments, edge 1920 of shield structure 1910 may be positioned (e.g., along the Y-axis) such that a center of edge 1920 of shield structure 1910 is aligned or approximately aligned with a center of a hole of conductor structure 910 and/or conductor structure 920. In some embodiments, edge 1920 of shield structure 1910 may be positioned (e.g., along the Y-axis) such that a length (e.g., length 2050) of edge 1920 of shield structure 1910 extends over a length of the bridges of conductor structure 910 and/or conductor structure 920 along the Y-axis.

FIG. 20 is a diagram 2000 of example shield structure 1910 of FIG. 19. As shown in FIG. 20, shield structure 1910 may have a height 2035 of a first edge 1920 along a Z-axis direction, a height 1950 of a second edge 1930 along the Z-axis direction, a thickness 2010 (along an X-axis direction for edges 1920, 1930, and along the Z-axis for connector portion 1940), a length 2050 of edges 1920, 1930 and connector portion 1940 along a Y-axis direction, and a distance 2045 of connector portion 1910 along the X-axis direction connecting edges 1920, 1930.

In some embodiments, shield structure 1910 may have a height 2035 of a first edge 1920 in a range between 2 mm and 30 mm, though the disclosure is not so limited. In some embodiments, shield structure 1910 may have a height 2035 of a first edge 1920 in a range between 5 mm and 15 mm, though the disclosure is not so limited. In some embodiments, shield structure 1910 may have a height 2035 of a first edge 1920 of approximately 15 mm, though the disclosure is not so limited.

In some embodiments, shield structure 1910 may have a height 1950 of a second edge 1930 in a range between 2 mm and 30 mm, though the disclosure is not so limited. In some embodiments, shield structure 1910 may have a height 1950 of a second edge 1930 in a range between 5 mm and 15 mm, though the disclosure is not so limited. In some embodiments, shield structure 1910 may have a height 1950 of a second edge 1930 of approximately 15 mm, though the disclosure is not so limited.

In some embodiments, height 2035 of first edge 1920 of shield structure 1910 may be the same as height 1950 of second edge 1930 of shield structure 1910. In some embodiments, height 2035 of first edge 1920 of shield structure 1910 may be different than height 1950 of second edge 1930 of shield structure 1910.

In some embodiments, shield structure 1910 may have a thickness 2010 in a range between 0.05 mm and 2 mm, though the disclosure is not so limited. In some embodiments, shield structure 1910 may have a thickness 2010 in a range between 0.1 mm and 1 mm, though the disclosure is not so limited. In some embodiments, shield structure 1910 may have a thickness of approximately 0.5 mm, though the disclosure is not so limited.

In some embodiments, shield structure 1910 may have lengths 2050 of edges 1920, 1930 and connector portion 1940 in a range between 5 mm and 40 mm, though the disclosure is not so limited. In some embodiments, shield structure 1910 may have lengths 2050 of edges 1920, 1930 and connector portion 1940 in a range between 10 mm and 20 mm, though the disclosure is not so limited. In some embodiments, shield structure 1910 may have lengths 2050 of edges 1920, 1930 and connector portion 1940 of approximately 15 mm, though the disclosure is not so limited.

In some embodiments, lengths 2050 of edges 1920, 1930, and connector portion 1940 may be the same. In some embodiments, lengths 2050 of edges 1920, 1930, and/or connector portion 1940 may be different.

In some embodiments, shield structure 1910 may have a distance 2045 of connector portion 1940 in a range between 10 mm and 60 mm, though the disclosure is not so limited. In some embodiments, shield structure 1910 may have a distance 2045 of connector portion 1940 in a range between 15 mm and 40 mm, though the disclosure is not so limited. In some embodiments, shield structure 1910 may have a distance 2045 of connector portion 1940 of approximately 23 mm, though the disclosure is not so limited.

Although example dimensions of shield structure 1910 have been provided above, the disclosure is not limited to these dimensions. A person of ordinary skill in the art would recognize that a variety of different dimensions and configurations of a shield structure may be used. Any dimensions and/or configurations of a shield structure that perform substantially the same function in substantially the same way to achieve substantially the same result should be considered to be within the scope of the disclosure herein. For example, one of skill in the art would recognize that dimensions and configurations of a shield structure may be varied if the dimensions of one or more conductor structures (e.g., conductor structure 910, conductor structure 920) are varied and/or if a different type of current sensor device is used. One of skill in the art would also recognize that dimensions and configurations of a shield may be varied depending on the needs of a particular application and/or a desired result (e.g., improved crosstalk performance, improved coupling factor, improved gain, improved frequency response). Such variations should be considered to be within the scope of the disclosure herein.

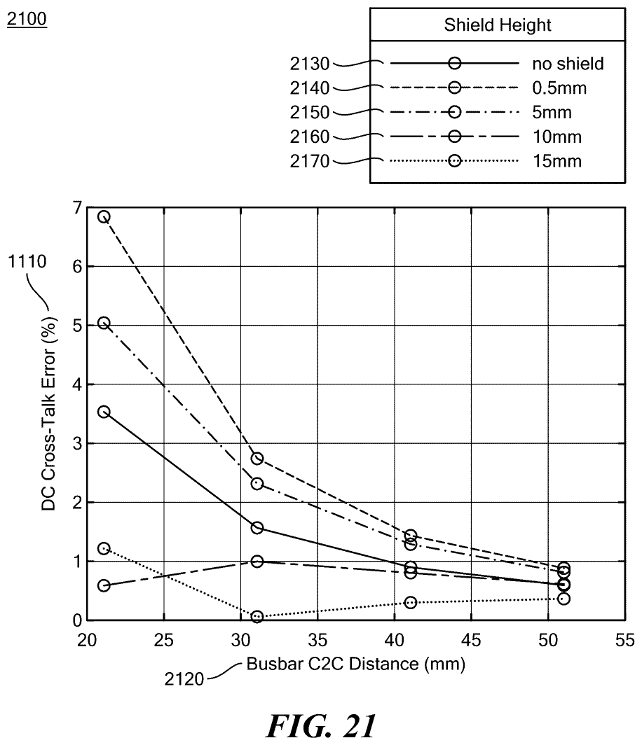

FIG. 21 is a graph 2100 of simulation results, with plots representing how crosstalk error varies for a current sensor device measuring current flowing in a conductor structure in the system of FIG. 19, based on a center-to-center distance between the conductor structures in the system and based on a height of an edge of a U-shaped shield structure positioned between the conductor structures in the system. Graph 2100 includes a Y-axis 1110 representing crosstalk error as a percentage of the current measured by a current sensor device, and an X-axis 2120 representing a center-to-center distance between the conductor structures, in mm.

Plot 2130 shows how the crosstalk error varies as the center-to-center distance between the conductor structures varies in system 1900 when no shield structure is positioned between the conductor structures. Plot 2140 shows how the crosstalk error varies as the center-to-center distance between the conductor structures varies in system 1900 when a U-shaped shield structure edge (e.g., edge 1920) with a height (e.g., height 2035) of 0.5 mm is positioned between the conductor structures in the system. Plot 2150 shows how the crosstalk error varies as the center-to-center distance between the conductor structures varies in system 1900 when a U-shaped shield structure edge (e.g., edge 1920) with a height (e.g., height 2035) of 5 mm is positioned between the conductor structures in the system. Plot 2160 shows how the crosstalk error varies as the center-to-center distance between the conductor structures varies in system 1900 when a U-shaped shield structure edge (e.g., edge 1920) with a height (e.g., height 2035) of 10 mm is positioned between the conductor structures in the system. Plot 2170 shows how the crosstalk error varies as the center-to-center distance between the conductor structures varies in system 1900 when a U-shaped shield structure edge (e.g., edge 1920) with a height (e.g., height 2035) of 15 mm is positioned between the conductor structures in the system.

As shown in FIG. 21, when a U-shaped shield structure edge (e.g., edge 1920) with a height (e.g., height 2035) of 0.5 mm or of 5 mm is positioned between the conductor structures in the system, the crosstalk error is worse than when no shield structure is used in the system. However, when a U-shaped shield structure edge (e.g., edge 1920) with a height (e.g., height 2035) of 10 mm or 15 mm is used in the system, the crosstalk error is improved than when no shield structure is used in the system. As shown in FIG. 21, when a center-to-center distance between the conductor structures of the system was less than 25 mm, use of a U-shaped shield structure edge (e.g., edge 1920) with a height (e.g., height 2035) of 10 mm yielded the lowest crosstalk error. When a center-to-center distance between the conductor structures of the system was greater than 25 mm, use of a U-shaped shield structure edge (e.g., edge 1920) with a height (e.g., height 2035) of 15 mm yielded the lowest crosstalk error. As shown in FIG. 21, the overall lowest crosstalk error simulated occurred when a U-shaped shield structure edge (e.g., edge 1920) with a height (e.g., height 2035) of 15 mm was used in the system, and when the center-to-center distance between the conductor structures in the system was approximately 31 mm (e.g., approximately 15 mm edge-to-edge distance between the conductor structures).

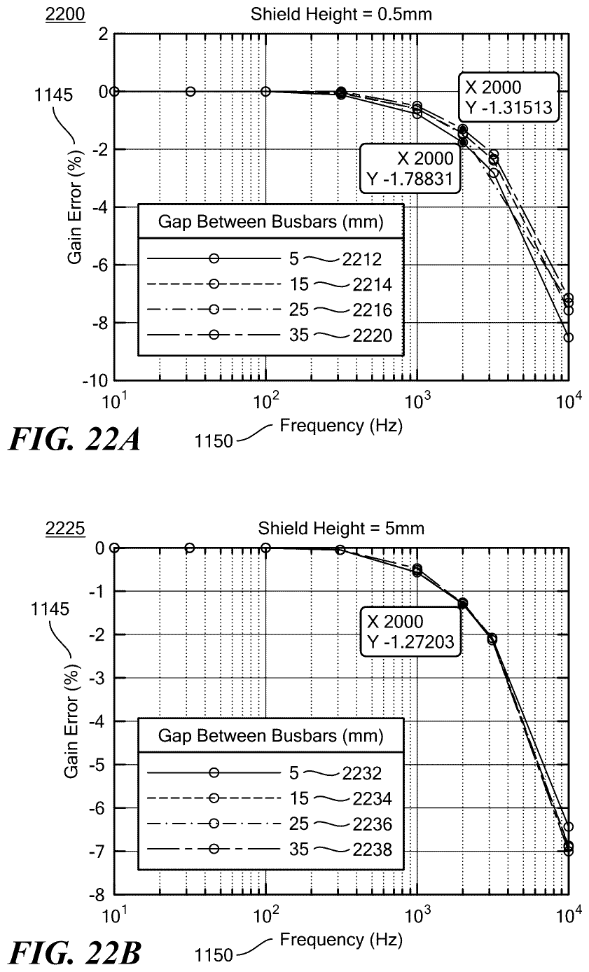

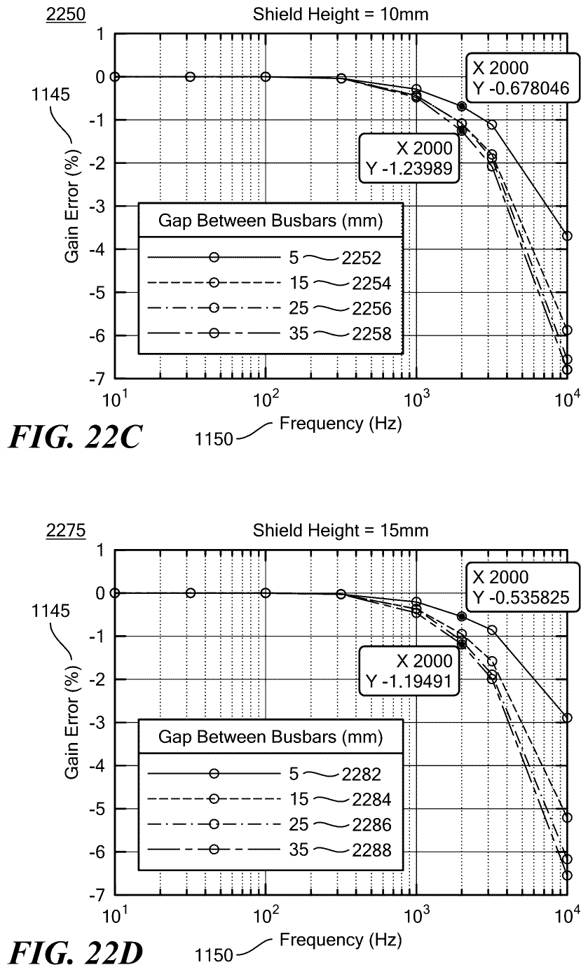

FIG. 22A is a graph 2200 of simulation results, with plots representing how gain error varies for a current sensor device measuring current flowing in a conductor structure in the system of FIG. 19, where a U-shaped shield structure edge (e.g., edge 1920) with a height (e.g., height 2035) of 0.5 mm was used, based on a distance (e.g., distance 1960) between the conductor structures and a frequency of the current being measured. Graph 2200 includes a Y-axis 1145 representing gain error, and an X-axis 1150 representing a frequency of the current.

Plot 2212 shows the gain error over frequency when a distance (e.g., distance 1960) between the conductor structures is 5 mm. Plot 2214 shows the gain error over frequency when a distance (e.g., distance 1960) between the conductor structures is 15 mm. Plot 2216 shows the gain error over frequency when a distance (e.g., distance 1960) between the conductor structures is 25 mm. Plot 2220 shows the gain error over frequency when a distance (e.g., distance 1960) between the conductor structures is 35 mm. As shown in FIG. 22A, the simulated amount of gain error when the current was at a frequency of 2000 Herz (Hz) was 1.78831% for the smallest gap between conductor structures plotted (i.e., plot 2212) and 1.31513% for the largest gap between conductor structures plotted (i.e., plot 2220).

FIG. 22B is a graph 2225 of simulation results, with plots representing how gain error varies for a current sensor device measuring current flowing in a conductor structure in the system of FIG. 19, where a U-shaped shield structure edge (e.g., edge 1920) with a height (e.g., height 2035) of 5 mm was used, based on a distance (e.g., distance 1960) between the conductor structures and a frequency of the current being measured. Graph 2225 includes a Y-axis 1145 representing gain error, and an X-axis 1150 representing a frequency of the current.

Plot 2232 shows the gain error over frequency when a distance (e.g., distance 1960) between the conductor structures is 5 mm. Plot 2234 shows the gain error over frequency when a distance (e.g., distance 1960) between the conductor structures is 15 mm. Plot 2236 shows the gain error over frequency when a distance (e.g., distance 1960) between the conductor structures is 25 mm. Plot 2238 shows the gain error over frequency when a distance (e.g., distance 1960) between the conductor structures is 35 mm. As shown in FIG. 22B, the simulated amount of gain error when the current was at a frequency of 2000 Hz was about 1.27203% regardless of the gap between the conductor structures.

FIG. 22C is a graph 2250 of simulation results, with plots representing how gain error varies for a current sensor device measuring current flowing in a conductor structure in the system of FIG. 19, where a U-shaped shield structure edge (e.g., edge 1920) with a height (e.g., height 2035) of 10 mm was used, based on a distance (e.g., distance 1960) between the conductor structures and a frequency of the current being measured. Graph 2250 includes a Y-axis 1145 representing gain error, and an X-axis 1150 representing a frequency of the current.

Plot 2252 shows the gain error over frequency when a distance (e.g., distance 1960) between the conductor structures is 5 mm. Plot 2254 shows the gain error over frequency when a distance (e.g., distance 1960) between the conductor structures is 15 mm. Plot 2256 shows the gain error over frequency when a distance (e.g., distance 1960) between the conductor structures is 25 mm. Plot 2258 shows the gain error over frequency when a distance (e.g., distance 1960) between the conductor structures is 35 mm. As shown in FIG. 22C, the simulated amount of gain error when the current was at 2000 Hz was 0.678046% for the smallest gap between conductor structures plotted (i.e., plot 2252) and 1.23989% for the largest gap between conductor structures plotted (i.e., plot 2258).

FIG. 22D is a graph 2275 of simulation results, with plots representing how gain error varies for a current sensor device measuring current flowing in a conductor structure in the system of FIG. 19, where a U-shaped shield structure edge (e.g., edge 1920) with a height (e.g., height 2035) of 15 mm was used, based on a distance (e.g., distance 1960) between the conductor structures and a frequency of the current being measured. Graph 2275 includes a Y-axis 1145 representing gain error, and an X-axis 1150 representing a frequency of the current.

Plot 2282 shows the gain error over frequency when a distance (e.g., distance 1960) between the conductor structures is 5 mm. Plot 2284 shows the gain error over frequency when a distance (e.g., distance 1960) between the conductor structures is 15 mm. Plot 2286 shows the gain error over frequency when a distance (e.g., distance 1960) between the conductor structures is 25 mm. Plot 2288 shows the gain error over frequency when a distance (e.g., distance 1960) between the conductor structures is 35 mm. As shown in FIG. 22D, the simulated amount of gain error when the current was at 2000 Hz was 0.535825% for the smallest gap between conductor structures plotted (i.e., plot 2282) and 1.19491% for the largest gap between conductor structures plotted (i.e., plot 2288).

When the same conductor structures were positioned apart from each other by 5 mm and no shield was used in the system of FIG. 19, the simulated gain error when the current was at 2000 Hz was 1.03%. Thus, use of a U-shaped shield structure with an edge (e.g., edge 1920) with a height (e.g., height 2035) of 10 mm or 15 mm in the system of FIG. 19, with the conductor structures spaced apart by 5 mm (or even 15 mm), may improve the frequency response of the current sensor device over the system of FIG. 19 when no shield structure is used.

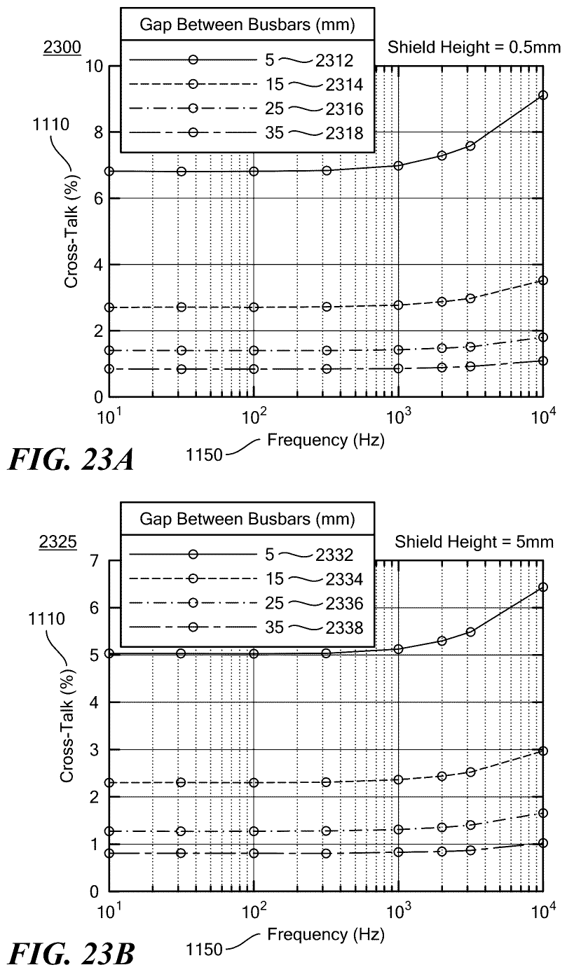

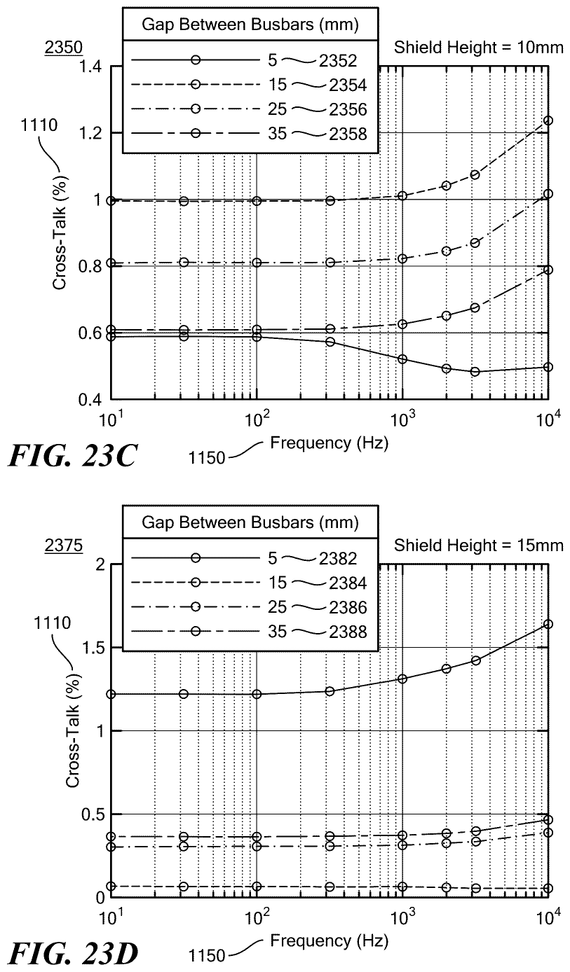

FIG. 23A is a graph 2300 of simulation results, with plots representing how crosstalk error varies for a current sensor device measuring current flowing in a conductor structure in the system of FIG. 19, where a U-shaped shield structure edge (e.g., edge 1920) with a height (e.g., height 2035) of 0.5 mm was used, based on a distance (e.g., distance 1960) between the conductor structures and a frequency of the current being measured. Graph 2300 includes a Y-axis 1110 representing crosstalk error, and an X-axis 1150 representing frequency of the current.

Plot 2312 shows the crosstalk error over frequency when a distance (e.g., distance 1960) between the conductor structures is 5 mm. Plot 2314 shows the crosstalk error over frequency when a distance (e.g., distance 1960) between the conductor structures is 15 mm. Plot 2316 shows the crosstalk error over frequency when a distance (e.g., distance 1960) between the conductor structures is 25 mm. Plot 2318 shows the crosstalk error over frequency when a distance (e.g., distance 1960) between the conductor structures is 35 mm.

FIG. 23B is a graph 2325 of simulation results, with plots representing how crosstalk error varies for a current sensor device measuring current flowing in a conductor structure in the system of FIG. 19, where a U-shaped shield structure edge (e.g., edge 1920) with a height (e.g., height 2035) of 5 mm was used, based on a distance (e.g., distance 1960) between the conductor structures and a frequency of the current being measured. Graph 2325 includes a Y-axis 1110 representing crosstalk error, and an X-axis 1150 representing frequency of the current.

Plot 2332 shows the crosstalk error over frequency when a distance (e.g., distance 1960) between the conductor structures is 5 mm. Plot 2334 shows the crosstalk error over frequency when a distance (e.g., distance 1960) between the conductor structures is 15 mm. Plot 2336 shows the crosstalk error over frequency when a distance (e.g., distance 1960) between the conductor structures is 25 mm. Plot 2338 shows the crosstalk error over frequency when a distance (e.g., distance 1960) between the conductor structures is 35 mm.

FIG. 23C is a graph 2350 of simulation results, with plots representing how crosstalk error varies for a current sensor device measuring current flowing in a conductor structure in the system of FIG. 19, where a U-shaped shield edge (e.g., edge 1920) with a height (e.g., height 2035) of 10 mm was used, based on a distance (e.g., distance 1960) between the conductor structures and a frequency of the current being measured. Graph 2350 includes a Y-axis 1110 representing crosstalk error, and an X-axis 1150 representing frequency of the current.

Plot 2352 shows the crosstalk error over frequency when a distance (e.g., distance 1960) between the conductor structures is 5 mm. Plot 2354 shows the crosstalk error over frequency when a distance (e.g., distance 1960) between the conductor structures is 15 mm. Plot 2356 shows the crosstalk error over frequency when a distance (e.g., distance 1960) between the conductor structures is 25 mm. Plot 2358 shows the crosstalk error over frequency when a distance (e.g., distance 1960) between the conductor structures is 35 mm.

FIG. 23D is a graph 2375 of simulation results, with plots representing how crosstalk error varies for a current sensor device measuring current flowing in a conductor structure in the system of FIG. 19, where a U-shaped shield edge (e.g., edge 1920) with a height (e.g., height 2035) of 15 mm was used, based on a distance (e.g., distance 1960) between the conductor structures and a frequency of the current being measured. Graph 2375 includes a Y-axis 1110 representing crosstalk error, and an X-axis 1150 representing frequency of the current.

Plot 2382 shows the crosstalk error over frequency when a distance (e.g., distance 1960) between the conductor structures is 5 mm. Plot 2384 shows the crosstalk error over frequency when a distance (e.g., distance 1960) between the conductor structures is 15 mm. Plot 2386 shows the crosstalk error over frequency when a distance (e.g., distance 1960) between the conductor structures is 25 mm. Plot 2388 shows the crosstalk error over frequency when a distance (e.g., distance 1960) between the conductor structures is 35 mm.

As can be seen from FIGS. 23A-23D, from the simulations with the U-shaped shield structure in the system of FIG. 19, the lowest crosstalk error occurred when a U-shaped shield structure with an edge (e.g., edge 1920) with a height (e.g., height 2035) of 15 mm was used in the system, and when the conductor structures were positioned apart by 15 mm. This crosstalk error stayed low across the entire simulated frequency range.

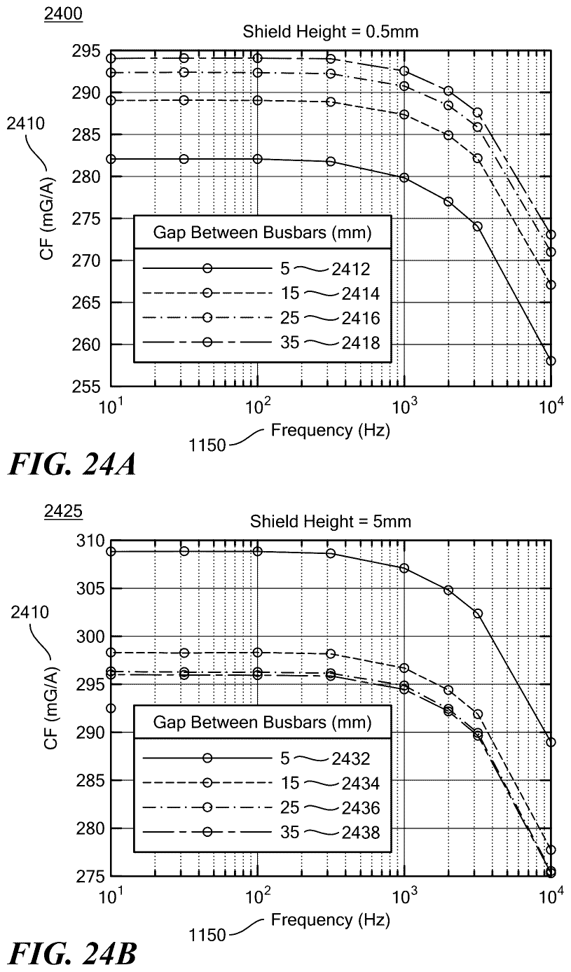

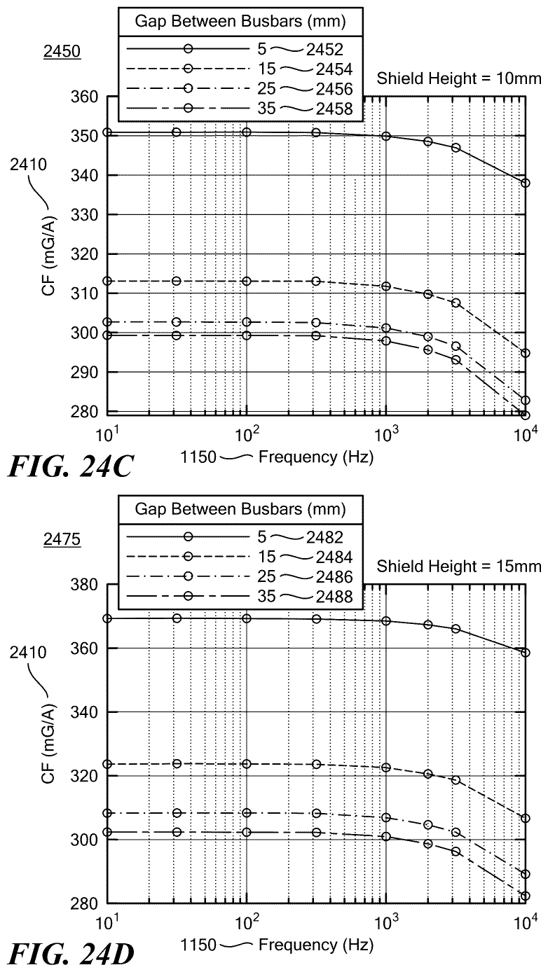

FIG. 24A is a graph 2400 of simulation results, with plots representing how coupling factor (in milliGauss (mG)/Ampere (A)) varies for a current sensor device measuring current flowing in a conductor structure in the system of FIG. 19, where a U-shaped shield structure edge (e.g., edge 1920) with a height (e.g., height 2035) of 0.5 mm was used, based on a distance (e.g., distance 1960) between the conductor structures and a frequency of the current being measured. Graph 2400 includes a Y-axis 2410 representing coupling factor, and an X-axis 1150 representing a frequency of the current.

Plot 2412 shows the coupling factor over frequency when a distance (e.g., distance 1960) between the conductor structures is 5 mm. Plot 2414 shows the coupling factor over frequency when a distance (e.g., distance 1960) between the conductor structures is 15 mm. Plot 2416 shows the coupling factor over frequency when a distance (e.g., distance 1960) between the conductor structures is 25 mm. Plot 2418 shows the coupling factor over frequency when a distance (e.g., distance 1960) between the conductor structures is 35 mm.

FIG. 24B is a graph 2425 of simulation results, with plots representing how coupling factor varies for a current sensor device measuring current flowing in a conductor structure in the system of FIG. 19, where a U-shaped shield structure edge (e.g., edge 1920) with a height (e.g., height 2035) of 5 mm was used, based on a distance (e.g., distance 1960) between the conductor structures and a frequency of the current being measured. Graph 2425 includes a Y-axis 2410 representing coupling factor, and an X-axis 1150 representing frequency of the current.

Plot 2432 shows the coupling factor over frequency when a distance (e.g., distance 1960) between the conductor structures is 5 mm. Plot 2434 shows the coupling factor over frequency when a distance (e.g., distance 1960) between the conductor structures is 15 mm. Plot 2436 shows the coupling factor over frequency when a distance (e.g., distance 1960) between the conductor structures is 25 mm. Plot 2438 shows the coupling factor over frequency when a distance (e.g., distance 1960) between the conductor structures is 35 mm.

FIG. 24C is a graph 2450 of simulation results, with plots representing how coupling factor varies for a current sensor device measuring current flowing in a conductor structure in the system of FIG. 19, where a U-shaped shield structure edge (e.g., edge 1920) with a height (e.g., height 2035) of 10 mm was used, based on a distance (e.g., distance 1960) between the conductor structures and a frequency of the current being measured. Graph 2450 includes a Y-axis 2410 representing coupling factor, and an X-axis 1150 representing a frequency of the current.

Plot 2452 shows the coupling factor over frequency when a distance (e.g., distance 1960) between the conductor structures is 5 mm. Plot 2454 shows the coupling factor over frequency when a distance (e.g., distance 1960) between the conductor structures is 15 mm. Plot 2456 shows the coupling factor over frequency when a distance (e.g., distance 1960) between the conductor structures is 25 mm. Plot 2458 shows the coupling factor over frequency when a distance (e.g., distance 1960) between the conductor structures is 35 mm.

FIG. 24D is a graph 2475 of simulation results, with plots representing how coupling factor varies for a current sensor device measuring current flowing in a conductor structure in the system of FIG. 19, where a U-shaped shield structure edge (e.g., edge 1920) with a height (e.g., height 2035) of 15 mm was used, based on a distance (e.g., distance 1960) between the conductor structures and a frequency of the current flowing being measured. Graph 2475 includes a Y-axis 2410 representing coupling factor, and an X-axis 1150 representing a frequency of the current.

Plot 2482 shows the coupling factor over frequency when a distance (e.g., distance 1960) between the conductor structures is 5 mm. Plot 2484 shows the coupling factor over frequency when a distance (e.g., distance 1960) between the conductor structures is 15 mm. Plot 2486 shows the coupling factor over frequency when a distance (e.g., distance 1960) between the conductor structures is 25 mm. Plot 2488 shows the coupling factor over frequency when a distance (e.g., distance 1960) between the conductor structures is 35 mm.

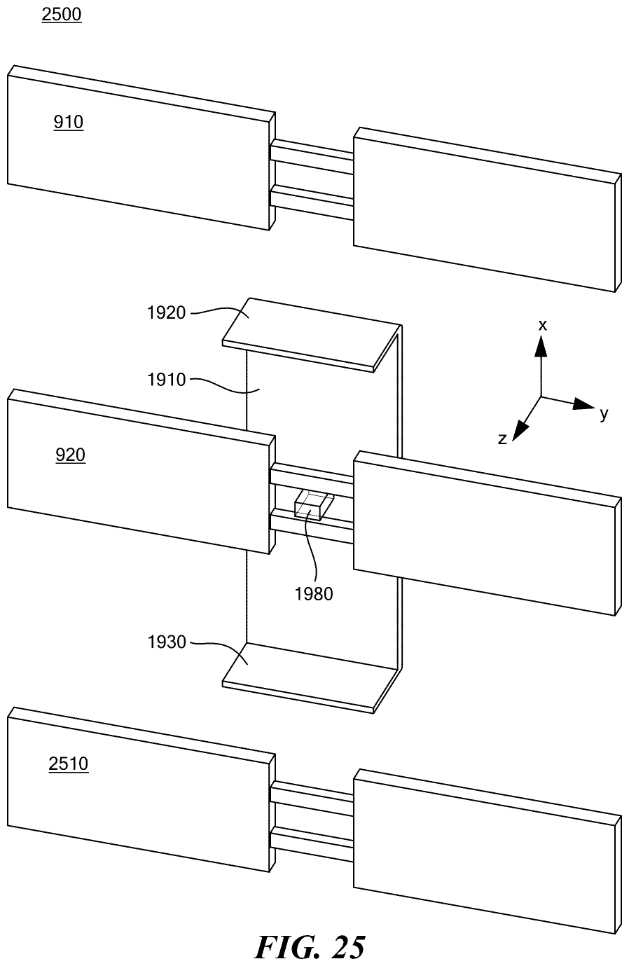

FIG. 25 is a diagram of an example system 2500 including three conductor structures 910, 920, 2510 positioned in proximity to each other, with an example U-shaped shield structure 1910 with edges 1920, 1930 positioned between the adjacent conductor structures. For example, edge 1920 of U-shaped shield structure 1910 is positioned between conductor structure 910 and conductor structure 920, as previously discussed. Edge 1930 of U-shaped shield structure 1910 is positioned between conductor structure 920 and conductor structure 2510. Edge 1930 may be positioned, dimensioned, and/or oriented with respect to conductor structure 920 and conductor structure 2510 in the same manner as edge 1920 is positioned, dimensioned, and oriented with respect to conductor structure 920 and conductor structure 910 (see FIG. 19 and related discussion). A current sensor device 1980 is positioned to measure current in conductor structure 920. Although not shown, a current sensor device may also be positioned in the hole of conductor structure 910, for measuring current in conductor structure 910, and a current sensor device may also be positioned in the hole of conductor structure 2510, for measuring current in conductor structure 2510.

System 2500 may be a system of conductor structures, a shield structure, and current sensor devices for use in a three-phase power system. In some embodiments, conductor structures 910, 920, and 2510 may correspond to conductor structures 108A, 108B, 108C of FIG. 1, and the three current sensor devices (each one in a respective hole of one of conductor structures 910, 920, 2510) may correspond to current sensor devices 110A, 110B, 110C of FIG. 1. As previously discussed, the current sensor devices may be coupled via their pins to wires and/or PCBs, which may be further coupled to a controller (e.g., ECU), such as controller 101 of FIG. 1. The controller may use the current measurements received from the current sensor devices to control a power source (e.g., power source 102) and/or load (e.g., load 104). As previously discussed, the disclosure herein should not be limited to a three-phase power system. As just one example, a six-phase power system may be implemented using six adjacent conductor structures, four U-shaped shield structures, and six current sensor devices.

Although certain example dimensions of conductor structures and shield structures, and example distances between the conductor structures and shield structures, were discussed and simulated above, the disclosure is not limited to these dimensions. A person of ordinary skill in the art would recognize that any of these dimensions and/or distances may be varied to achieve a desired result (e.g., reduced crosstalk error, reduced gain error, improved coupling factor, improved frequency response) for a particular application.

Although examples discussed herein primarily included dual bridge (or vertical slit) conductor structures, the disclosure is not so limited. A conductor structure used in the examples discussed herein may instead comprise conductor structure 210, conductor structure 510, conductor structure 570 (i.e., conductive trace(s) on a PCB), conductor structure 810, conductor structure 1810, conductor structure 1820, or other types of conductor structures.

Although examples discussed herein primarily included conductor structures arrangement in a standard vertical slit arrangement, the disclosure is not so limited. Conductor structures may instead be arranged in a stacked arrangement (see, e.g., FIG. 7B) or other type of arrangement.

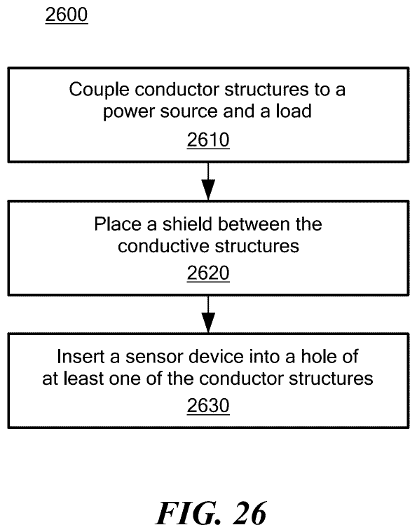

FIG. 26 is an example process 2600 for configuring a system including example conductor structures, an example shield structure, and an example current sensor device. The example conductor structures may, for example, be conductor structures 910, 920 as previously discussed, though the disclosure is not so limited. Alternatively, the conductor structures may be two of conductor structures 510, two of conductor structures of 570, conductor structures 710, 720, conductor structures 760, 770, or conductor structures 1810, 1820, though the disclosure is not so limited. In some embodiments, the conductor structures may be a combination of different types of any of the conductor structures previously discussed herein, though the disclosure is not so limited.

The current sensor device may be current sensor device 650, though the disclosure is not so limited. Alternatively, the current sensor device may be current sensor device 250, current sensor device 505, current sensor device 555, current sensor device 930, current sensor device 940, current sensor device 1720, or current sensor device 1980, though the disclosure is not so limited.

The shield structure may be a flat shield structure (e.g., shield structure 950, shield structure 1730) or a U-shaped shield structure (e.g., shield structure 1910), though the disclosure is not so limited.

In 2610, conductor structures (e.g., conductor structures 910, 920) may be coupled to a power source (e.g., power source 102 of system 100 of FIG. 1) and to a load (e.g., load 104 of system 100 of FIG. 1). For example, conductive clamps or some other type of connection may be used to connect a conductor structure to the power source and the load. In some embodiments, the conductor structures may be coupled to the power source and load by coupling connectors to connection points, such as circular voids created in the conductor structure. In some embodiments, the conductor structures may be coupled to different power sources and/or to different loads.

In 2620, a shield structure (e.g., shield structure 950, shield structure 1910) may be placed between the conductor structures. For example, a flat shield structure (e.g., shield structure 950) may be positioned between (e.g., approximately halfway between) conductor structures as shown in FIGS. 9, 12, 15A, 16A, 17, and 18A, though the disclosure is not so limited. If three conductor structures were coupled in 2610, two flat shield structures may be placed (see, e.g., FIG. 17) or one U-shaped shield structure may be placed (see, e.g., FIG. 25). In some embodiments, a U-shaped shield structure (e.g., shield structure 1910) may placed such that an edge (e.g., edge 1920, edge 1930) of the U-shaped shield structure is positioned between (e.g., approximately halfway between) conductor structures as shown in FIGS. 19 and 25.

In 2630, a current sensor device (e.g., current sensor device 650) may be inserted into a hole of one of the conductor structures. For example, a current sensor device may be inserted into a hole of a conductor structure, as shown in FIGS. 5A, 6A, 6B, 9, 17, 19, or 25. Alternatively, a current sensor device may be placed in proximity to a conductor structure, as shown in FIGS. 2, 3, or 5B. As previously discussed, the current sensor device may be positioned such that the magnetic field sensing elements of the current sensor device are maximally sensitive to the magnetic field in a direction perpendicular to the lengthwise direction of the conductor structure (i.e., in a direction towards the other conductor structure).

One of skill in the art would recognize that steps 2610, 2620, and 2630 may be performed in a different order, or performed simultaneously. For example, a shield structure could first be placed and conductor structures and sensor devices then disposed around the shield structure's location. Alternatively, the current sensor device could first be placed, and the conductor structures and shield structure then disposed around the current sensor device's location.

In a system (e.g., system 100 of FIG. 1), the conductor structures, shield structures, current sensor devices may be fixed in place. For example, the conductor structures, shield structures, and/or current sensor devices may be mounted in positions by bolts, screws, adhesives, or other fasteners. In some embodiments, the current sensor device may be coupled to a PCB positioned proximate to the conductor structure. In some embodiments, coupling of the current sensor device to the PCB may function to fix the current sensor device in place. In some embodiments, the current sensor device may be fixed in position by a fastener, such as a screw or adhesive. A PCB and/or wires may be used to couple the current sensor device to a controller (e.g., controller 101 of system 100 of FIG. 1), such that current measurements taken by the current sensor device may be sent to the controller, and the controller may act upon the measurements to make adjustments to a power source (e.g., power source 102 of system 100 of FIG. 1) and/or to a load (e.g., load 104 of system 100 of FIG. 1). As previously discussed, placement of the current sensor device relative to the conductor structure may change due to vibration, temperature changes, or other fluctuations in a system. However, placement of the current sensor device in a hole of a conductor structure may reduce the impact of these misplacements on the current sensor device's current sensing accuracy. As previously discussed, positioning of a shield structure between the conductor structures may serve to reduce crosstalk error, reduce gain error, improve coupling factor, and/or improve frequency response of current sensor devices in a system.

Process 2600 may be repeated for additional conductor structures and additional current sensor devices. That is, in 2610 a third conductor structure may be coupled to a power source (e.g., power source 102 of system 100 of FIG. 1) and a load (e.g., load 104 of system 100 of FIG. 1). In 2620, a second shield structure may be placed between one of the conductor structures and the third conductor structure, or a second edge of a U-shaped shield structure may be placed between one of the conductor structures and the third conductor structure. In 2630, a second current sensor device may be inserted into a hole of another conductor structure. In 2630, a third current sensor device may also be inserted into a hole of the third conductor structure.

Process 2600 may be repeated for any number of conductor structures, shield structures, and current sensor devices. For example, in a three-phase power system, it may be desired to utilize three conductor structures, two flat shield structures (or one U-shaped shield structure with two edges), and three current sensor devices, as previously discussed. For example, system 100 of FIG. 1 comprises three conductor structures 108A, 108B, 108C (each of which may be a conductor structure 810) and three current sensor devices (each of which may be a current sensor device 550). In a six-phase power system, it may be desired to utilize six conductor structures, five flat shield structures (or four U-shaped shield structures each with two edges), and six current sensor devices, as previously discussed. Of course, the disclosure is not limited to any particular number of conductor structures, shield structures, and current sensor devices. One of skill in the art would recognize that any N number of conductor structures, shield structures, and current sensor devices may be utilized in a system.

Although the conductor structures, shield structures, and current sensor devices are described herein primarily in reference to electric vehicle systems, the disclosure is not so limited. The conductor structures, shield structures, and current sensor devices described herein may be utilized in any system for that provides current and measures the current provided. For example, the conductor structures, shield structures, and current sensor devices described herein may be widely applicable in electric motor systems in applications ranging from electric vehicles to industrial operations.

As used herein, the terms “processor” and “controller” are used to describe electronic circuitry that performs a function, an operation, or a sequence of operations. The function, operation, or sequence of operations can be hard coded into the electronic circuit or soft coded by way of instructions held in a memory device. The function, operation, or sequence of operations can be performed using digital values or using analog signals. In some embodiments, the processor or controller can be embodied in an application specific integrated circuit (ASIC), which can be an analog ASIC or a digital ASIC, in a microprocessor with associated program memory and/or in a discrete electronic circuit, which can be analog or digital. A processor or controller can contain internal processors or modules that perform portions of the function, operation, or sequence of operations. Similarly, a module can contain internal processors or internal modules that perform portions of the function, operation, or sequence of operations of the module.

While electronic circuits shown in figures herein may be shown in the form of analog blocks or digital blocks, it will be understood that the analog blocks can be replaced by digital blocks that perform the same or similar functions and the digital blocks can be replaced by analog blocks that perform the same or similar functions. Analog-to-digital or digital-to-analog conversions may not be explicitly shown in the figures but should be understood.

Various embodiments of the systems and methods are described herein with reference to the related drawings. Alternative embodiments can be devised without departing from the scope of the described concepts. It is noted that various connections and positional relationships (e.g., over, below, adjacent, etc.) are set forth between elements in the following description and in the drawings. These connections and/or positional relationships, unless specified otherwise, can be direct or indirect, and the present invention is not intended to be limiting in this respect. Accordingly, a coupling of entities can refer to either a direct or an indirect coupling, and a positional relationship between entities can be a direct or indirect positional relationship. As an example of an indirect positional relationship, references in the present description to element or structure A over element or structure B include situations in which one or more intermediate elements or structures (e.g., element C) is between elements A and B regardless of whether the characteristics and functionalities of elements A and/or B are substantially changed by the intermediate element(s).

Furthermore, it should be appreciated that relative, directional or reference terms (e.g. such as “above,” “below,” “left,” “right,” “top,” “bottom,” “vertical,” “horizontal,” “front,” “back,” “rearward,” “forward,” etc.) and derivatives thereof are used only to promote clarity in the description of the figures. Such terms are not intended as, and should not be construed as, limiting. Such terms may simply be used to facilitate discussion of the drawings and may be used, where applicable, to promote clarity of description when dealing with relative relationships, particularly with respect to the illustrated embodiments. Such terms are not, however, intended to imply absolute relationships, positions, and/or orientations. For example, with respect to an object or structure, an “upper” or “top” surface can become a “lower” or “bottom” surface simply by turning the object over. Nevertheless, it is still the same surface and the object remains the same. Also, as used herein, “and/or” means “and” or “or,” as well as “and” and “or.”

The terms “disposed over,” “overlying,” “atop,” “on top,” “positioned on” or “positioned atop” mean that a first element, such as a first structure, is present on a second element, such as a second structure, where intervening elements or structures (such as an interface structure) may or may not be present between the first element and the second element. The term “direct contact” means that a first element, such as a first structure, and a second element, such as a second structure, are connected without any intermediary elements or structures between the interface of the two elements. The term “connection” can include an indirect connection and a direct connection.

It should be recognized that values described herein may be exact or approximate. One of ordinary skill in the art would recognize that values described herein may vary depending on, for example, manufacturing tolerances of components in sensor devices. As a result, values that deviate from a described value by up to +/−20% of the described value may be deemed to correspond to the value described.

In the foregoing detailed description, various features are grouped together in one or more individual embodiments for the purpose of streamlining the disclosure. This method of disclosure is not to be interpreted as reflecting an intention that each claim requires more features than are expressly recited therein. Rather, inventive aspects may lie in less than all features of each disclosed embodiment.

References in the disclosure to “one embodiment,” “an embodiment,” “some embodiments,” or variants of such phrases indicate that the embodiment(s) described can include a particular feature, structure, or characteristic, but every embodiment can include the particular feature, structure, or characteristic. Moreover, such phrases are not necessarily referring to the same embodiment(s). Further, when a particular feature, structure, or characteristic is described with reference to one embodiment, knowledge of one skilled in the art may be relied upon to affect such feature, structure, or characteristic in connection with other embodiments whether or not explicitly described.

The disclosed subject matter is not limited in its application to the details of construction and to the arrangements of the components set forth in the following description or illustrated in the drawings. The disclosed subject matter is capable of other embodiments and of being practiced and carried out in various ways. As such, those skilled in the art will appreciate that the conception, upon which this disclosure is based, may readily be utilized as a basis for the designing of other structures, methods, and systems for carrying out the several purposes of the disclosed subject matter. Therefore, the claims should be regarded as including such equivalent constructions insofar as they do not depart from the spirit and scope of the disclosed subject matter.

Although the disclosed subject matter has been described and illustrated in the foregoing exemplary embodiments, it is understood that the present disclosure has been made only by way of example, and that numerous changes in the details of implementation of the disclosed subject matter may be made without departing from the spirit and scope of the disclosed subject matter.

All publications and references cited herein are expressly incorporated herein by reference in their entirety.

1. A system, comprising:
a first conductor structure;
a second conductor structure spaced apart from the first conductor structure along a first dimension;
a shield structure positioned between the first conductor structure and the second conductor structure; and
a sensor device positioned in proximity to the first conductor structure, the sensor device comprising first and second magnetic field sensing elements configured to be sensitive to a magnetic field along the first dimension when current flows through the first conductor structure.

2. The system of claim 1, wherein the shield structure comprises a soft ferromagnetic material.

3. The system of claim 1, wherein the shield structure is shaped like a flat plate.

4. The system of claim 1, wherein the shield structure is U-shaped.

5. The system of claim 1, wherein the first conductor structure further has a width along the first dimension and a length longer than the width along a second dimension, the first conductor structure further comprising:
a first portion of the first conductor structure defining a hole passing through the first conductor structure;
a second portion of the first conductor structure defining a first notch out of a first side of the first conductor structure; and
a third portion of the first conductor structure defining a second notch out of a second side of the first conductor structure,
wherein the sensor device is positioned in the hole.

6. The system of claim 1, further comprising a third conductor structure spaced apart from the first conductor structure and the second conductor structure along the first dimension.

7. The system of claim 6, wherein the shield structure comprises a first shield structure, further comprising a second shield structure positioned between the second conductor structure and the third conductor structure.

8. The system of claim 6, wherein the shield structure is U-shaped, the shield structure further comprising:
a first edge positioned between the first conductor structure and the second conductor structure;
a second edge positioned between the second conductor structure and the third conductor structure; and
a connector portion connecting the first edge and the second edge.

9. The system of claim 6, wherein the first conductor structure, the second conductor structure, and the third conductor structure each comprise:
a first portion that forms a hole;
a second portion that forms a first notch out of a first side; and
a third portion that forms a second notch out of a second side.

10. The system of claim 9, wherein the sensor device is a first sensor device, wherein the first sensor device is positioned in the hole of the first conductor structure, further comprising:
a second sensor device positioned in the hole of the second conductor structure; and
a third sensor device positioned in the hole of the third conductor structure.

11. The system of claim 1, wherein at least one of the first and second magnetic field sensing elements is one of a Hall plate element or a tunneling magnetoresistance (TMR) element.

12. The system of claim 6, wherein the first conductor structure is configured to transmit a first alternating current, the second conductor structure is configured to transmit a second alternating current that is phase-shifted from the first alternating current, and the third conductor structure is configured to transmit a third alternating current that is phase-shifted from the first alternating current and that is phase-shifted from the second alternating current.

13. The system of claim 1, wherein at least one of the first conductor structure or the second conductor structure comprises a busbar.

14. The system of claim 1, wherein at least one of the first conductor structure or the second conductor structure comprises a circuit trace on a printed circuit board (PCB).

15. The system of claim 1, wherein the shield structure comprises at least one of Silicon Iron (SiFe), a Nickel Iron (NiFe) alloy, ferrite, or magnetic stainless steel.

16. The system of claim 8, wherein each of the first edge and the second edge extend at least 10 millimeters from the connector portion.

17. The system of claim 3, wherein the shield structure extends at least 5 millimeters in a second dimension orthogonal to the first dimension.

18. The system of claim 1, wherein the first conductor structure comprises a portion that forms a notch out of a side, wherein the sensor device is placed above or below a portion of the conductor structure that passes by the notch.

19. A method of configuring a current sensor system, comprising:
coupling a first conductor structure to a power source and a load;
coupling a second conductor structure to the power source and the load, the second conductor structure being spaced apart from the first conductor structure along a first dimension;
positioning a shield structure between the first conductor structure and the second conductor structure; and
positioning a sensor device in proximity to the first conductor structure, the sensor device comprising first and second magnetic field sensing elements configured to be sensitive to a magnetic field along the first dimension when current flows through the first conductor structure.

20. The method of claim 19, wherein the shield structure is a first shield structure, further comprising:
coupling a third conductor structure to the power source and the load, the third conductor structure being spaced apart from the first conductor structure and the second conductor structure along the first dimension; and
positioning a second shield structure between the second conductor structure and the third conductor structure.

21. The method of claim 19, further comprising:
positioning a first edge of the shield structure between the first conductor structure and the second conductor structure;
coupling a third conductor structure to the power source and the load, the third conductor structure being spaced apart from the first conductor structure and the second conductor structure along the first dimension; and
positioning a second edge of the shield structure between the second conductor structure and the third conductor structure.
